(19) United States
(12) Patent Application Publication
(10) Pub. No.: US 2024/0164057 A1
(43) Pub. Date: May 16, 2024

(54) Coolant Distribution Unit Pump Control

(71) Applicant: Hoffman Enclosures Inc., Anoka, MN (US)

(72) Inventors: Gabriel T.A. Schaap, Anoka, MN (US); Matthew R. Archibald, Derry, NH (US)

(21) Appl. No.: 18/511,834

(22) Filed: Nov. 16, 2023

Related U.S. Application Data
(60) Provisional application No. 63/383,939, filed on Nov. 16, 2022.

(51) Int. Cl. H05K 7/20

(52) U.S. Cl. CPC H05K 7/20281; H05K 7/20272; H05K 7/20172

(57) ABSTRACT

The disclosure provides a system and method for control of a pump in a coolant distribution unit (CDU) for cooling electronic components. In some aspects, the CDU includes a reservoir pump unit (RPU). Aspects of the method include setting a control priority to a first value indicative of a client mode in which a first local controller generates a first speed signal for a first pump in response to an instruction received from a master controller. The method includes determining a first interval since a last communication from the master controller. If the first interval exceeds a present dead time, the method includes setting the control priority of the first local controller to a second value indicative of an autonomous mode in which the first local controller generates the first speed signal for the first pump based on one or more parameters stored in a memory of the first local controller.

### CROSS-REFERENCE TO RELATED APPLICATIONS

This application claims priority to U.S. Provisional Patent Application No. 63/383,939 filed Nov. 16, 2022, the entirety of which is incorporated by reference.

### BACKGROUND

Cooling systems can be provided for data centers to cool electrical components. During operation, electrical components, typically housed in racks having a standard rack footprint (e.g., a standard height, width, and depth), generate heat. Excessive heat (e.g., heat producing a temperature above a safe operating temperature for the electrical components) may degrade electrical components, damage the systems, or degrade performance of the components. Cooling systems can be provided for data centers to transfer heat away from heat load within the data center.

### SUMMARY

The disclosure provides a system and method for control of a pump in a coolant distribution unit (CDU) for cooling electronic components. In some aspects, the CDU includes a master controller and a reservoir pump unit (RPU) with one or more pump cassettes having one or more local controllers.

Some aspects of the disclosure provide a system and method for controlling a first pump in a coolant distribution unit for cooling electronic components. The method can include setting a control priority to a first value indicative of a client mode in which a first local controller generates a first speed signal for the first pump in response to an instruction received from a master controller. A first interval since a last communication from the master controller can be determined. If the first interval exceeds a preset dead time, the control priority of the first local controller can be set to a second value indicative of an autonomous mode in which the first local controller generates the first speed signal for the first pump based on one or more parameters stored in a memory of the first local controller.fi of a pump in a CDU.

In some examples, the method can include generating, at the first local controller, a second speed signal based on the target speed. In some examples, the method includes determining that the first pump is a passive pump, and, when the first interval exceeds the preset dead time, generating, at the first local controller, a third speed signal to reduce a speed of the first pump. In some examples, a first pump cassette can include the first local controller, the first pump, a first pump drive, and at least one peripheral electronic device. In some examples the at least one electronic peripheral device can include a fan. In some examples, the first pump cassette includes a first power button. In some examples, a second pump cassette including a second local controller, a second pump, and a second pump drive can be provided. In some examples, a power button signal can be received indicating a depression of the first power button. In some examples, the master controller can generate, responsive to a power button signal, a first ramp instruction to increase a first speed of the first pump. In some examples, a first ramp instruction can be sent to the first local controller. In some examples, responsive to a power button signal, the master controller can generate a second ramp instruction to decrease a second speed of the second pump. In some example, the second ramp instruction can be sent to the second local controller. In some examples, the method can further include removing the second pump cassette while the first pump of the first pump cassette continues to operate in the autonomous mode. In some examples, communication between the master controller and the first local controller and the second local controller can adhere to a Modbus protocol. In some example, the method can further comprise controlling the first pump in a reservoir pump unit of a liquid to air coolant distribution unit. In some examples, a control priority of the first local controller can be set to the second value indicative of the autonomous mode when an emergency loss of communication occurs.

Some aspects of the disclosure provide a reservoir pump unit for use in a coolant distribution unit for cooling electrical components. The reservoir pump unit can include a controller slot a first cassette bay and a first pump cassette. The controller slot can receive a master controller, the master controller being configured for toolless removal from the controller slot. The first cassette bay can receive the first pump cassette. The first pump cassette can include a first pump and a first local controller. The first local controller can include a first memory with a first control priority set at a first value indicative of a client mode in which the first local controller receives a first speed instruction from the master controller. The first local controller can determine a first interval since a last communication from the master controller. When the first interval exceeds a preset dead time, the first local controller can set the first control priority to a second value indicative of an autonomous mode in which the first local controller generates a first speed signal for the first pump based on one or more parameters stored in the first memory.

In some examples, the coolant distribution unit further includes a second cassette bay receiving a second pump cassette, the second pump cassette including a second pump and a second local controller, wherein the first pump cassette includes a power button; and when the power button is depressed, the master controller generates a first ramp instruction to increase a speed of the first pump and a second ramp instruction to decrease a second speed of the second pump. In some examples, a communication between the master controller and the first local controller and the second local controller can adhere to a Modbus protocol. In some examples, when the first local controller is in the client mode, the first local controller can receive an instruction from the master controller to implement a first of a plurality of operating modes. In some examples, the first pump cassette can include a locking system to engage a locking mechanism of the reservoir pump unit to selectively lock or unlock the first pump cassette relative to the reservoir pump unit. In some examples, the locking system can be in electrical communication with the first local controller. In some examples, the coolant distribution unit can be a liquid to air coolant distribution unit including a plurality of fans. In some examples, the reservoir pump unit can be installed in a liquid to air coolant distribution unit. In some examples, the first local controller can set the first control priority to the second value indicative of the autonomous mode when an emergency loss of communication occurs.

### BRIEF DESCRIPTION OF THE DRAWINGS

The accompanying drawings, which are incorporated in and form a part of this specification, illustrate examples of the disclosed technology and, together with the description, serve to explain the principles of aspects of the disclosure:

FIG. 1A is a schematic illustration of an example cooling system for electrical components;

FIG. 1B is a schematic illustration of certain components of the cooling system of FIG. 1A, including a reservoir pump unit (RPU) with a hot-swappable pump cassette;

FIGS. 2-4 are plumbing schematics of example cooling systems for electrical components, including RPUs with sets of parallel-operation pump cassettes;

FIG. 5 is an isometric view of an RPU including a set of parallel-operation, hot-swappable pump cassettes, according to some aspects;

FIG. 6 is a schematic illustration of a control system for the cooling system of FIG. 3;

FIG. 7 is a flowchart illustrating a process for controlling pumps of an RPU, according to some aspects;

FIG. 8 is a flowchart illustrating a process for performing a switchover between pumps of an RPU, according to some aspects;

FIG. 9 is a flowchart illustrating an emergency operation process for pumps of an RPU, according to some aspects;

FIG. 10 is a flowchart illustrating a process for enabling or disabling pumps of an RPU, according to some aspects;

FIG. 11 is a flowchart illustrating a method of controlling fans of pump cassettes of an RPU, according to some aspects;

FIG. 12 is a flowchart illustrating a process for handling errors of an RPU according to some aspects;

FIG. 13 is a flowchart illustrating a LED control process for controlling LEDs of an RPU, according to some aspects; and

FIG. 14 is a another flowchart illustrating a LED control process for controlling LEDs of an RPU, according to some aspects

### DETAILED DESCRIPTION

Before any aspects of the disclosure are explained in detail, it is to be understood that the disclosure is not limited in its application to the details of construction and the arrangement of components set forth in the following description or illustrated in the following drawings. The disclosure is capable of other aspects and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

The following discussion is presented to enable a person skilled in the art to make and use aspects of the disclosure. Various modifications to the illustrated aspects will be readily apparent to those skilled in the art, and the generic principles herein can be applied to other aspects and applications without departing from aspects of the disclosure. Thus, aspects of the disclosure are not intended to be limited to aspects shown but are to be accorded the widest scope consistent with the principles and features disclosed herein. The following detailed description is to be read with reference to the figures, in which like elements in different figures have like reference numerals. The figures, which are not necessarily to scale, depict selected aspects and are not intended to limit the scope of aspects of the disclosure. Skilled artisans will recognize the examples provided herein have many useful alternatives and fall within the scope of aspects of the disclosure.

Cabinets or racks containing electrical equipment are typically arranged in rows within a data center, defining aisles between consecutive rows. Racks can be pre-assembled and “rolled in” to a space in the row adjacent to other racks, the space being pre-defined to have the footprint of a standard rack. This arrangement allows a modular construction of or addition to components in a data center. In some configurations, aisles on opposite sides of a rock of cabinets can be alternately designated as a cold aisle, or a hot aisle, and heat generated by the electrical components of a cabinet can be expelled to the hot air aisle.

Some examples of the technology disclosed herein can include coolant distribution units (CDUs), which generally include pump systems and associated components for use in moving fluid along liquid flow paths of cooling systems (e.g., primary or secondary flow loops for liquid cooling of servers or other electronics). In some examples, CDUs according to this disclosure can comprise liquid to air coolant distribution units. In particular, some examples include CDUs configured as reservoir pump units with components for liquid coolant distribution that can be readily installed into and removed from cooling systems, including during ongoing operation of the cooling systems in some aspects (i.e., with “hot-swappable” components). For example, a reservoir pump unit (RPU) can include an arrangement of components that allow individual pump cassettes to be selectively installed into or removed from a cooling system to provide redundant, hot-swappable pump capacity for a water or other liquid cooling flow. In some cases, an RPU can include structures of a larger cooling system that can receive and secure hot-swappable (or other) cassettes, and ensure appropriate alignment and leak prevention for liquid connections.

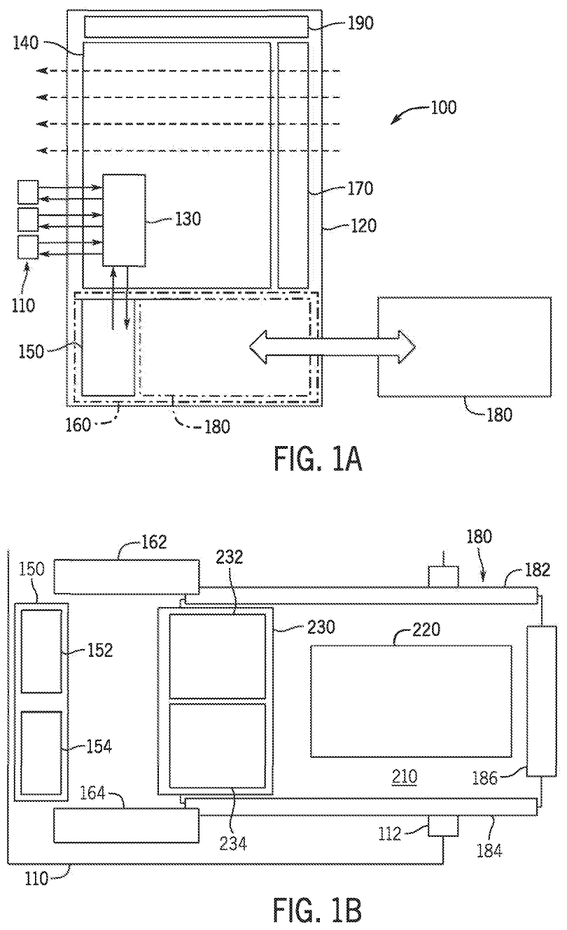

FIG. 1A illustrates a schematic for an example cooling system 100 configured to use air-to-liquid (ATL) heat exchange to transfer heat away from electrical equipment in various numbers of cabinets. (Although examples below focus on ATL arrangements, similar systems can generally be used with other cooling arrangements, including for liquid-to-liquid heat exchange, liquid to air heat exchange, or refrigeration cycles). In the illustrated aspect, three distinct racks 110 of electrical equipment are shown schematically on the left, with an in-row cooling device (ICD) 120 on the right. As further discussed below, the racks 110 can be connected to the ICD 120 with a variety of plumbing arrangements (e.g., known tubing, manifold, or valve arrangements) for flow of cooling fluid (e.g., water, propylene glycol, or other liquid coolant or refrigerant) to and from the racks 110. Thus, for example, cooler water can flow from the ICD 120 to the racks 110 to remove thermal energy from the electrical equipment therein, and hotter water can return from the racks 110 to the ICD 120.

In some examples, the ICD 120 can be housed in a rack having a standard rack footprint for modular assembly, ease of installation and integration within a data center. In other examples, the footprint of an in-row cooling device may be smaller than a standard rack footprint or otherwise sized.

In the illustrated example, a manifold 130 of the ICD 120 is arranged to receive and distribute fluid for flow between the ICD 120 and racks 110, as well as flow between a heat exchanger 140 and a flow connection module 150 of an RPU 160. Accordingly, when at least one pump unit of the RPU 160 operates to provide for cooling flow, the manifold 130 can direct to the heat exchanger 140 fluid that has been heated in the racks 110, and can also direct to the racks 110 fluid that has been cooled by the heat exchanger 140.

A wide variety of manifold configurations are possible. In some examples, the manifold 130 can include a unified assembly to support one or more of: connections (e.g., quick-connection fittings) and conduits for flow to and from the racks 110; connections and conduits for flow to and from the RPU 160; or connections and conduits for flow to and from the heat exchanger 140. In some examples, the manifold 130 can include distributed arrangements, including individual components or component assemblies distributed variously around the RPU 160 for connections and flow between these various sub-systems.

In some examples, the manifold 130 can include the connection module 150 as part of a unified assembly. In some example, including as shown in FIG. 1, the connection module 150 may be separate from a manifold for distribution of fluid to or from the racks 110 and flow components of various known types (e.g., tubing, fittings, valves, filters, etc.) can be arranged to allow flow between the connection module 150 and one or more other sub-systems of the cooling system 100 (e.g., the manifold 130 as shown in FIG. 1, the heat exchanger 140, the racks 110 without an intervening distinct manifold, etc.).

In some aspects, fans may be provided to generate an airflow across the heat exchanger 140, to increase a cooling efficiency of the system. In some aspects, the fans can further enhance a cooling of the system by directing the air toward a hot aisle, for example. In the illustrated example, a fan bank 170 is included in the ICD 120 to provide forced air flow across the heat exchanger 140 (see dashed arrows). (Although the air flow from the fan bank 170 is illustrated as being directed toward the racks 110, those of skill in the art will understand that actual implementations may locate the racks 110 out of the path of the heated air.) The fan bank 170 can include any number of fan modules, as appropriate, including hot-swappable fans arranged in vertical or laterally arrayed patterns.

In different implementations, the fan bank 170 can be at the side, front, or rear of the ICD 120, can be included on a door of the ICD 120, or can be otherwise located. In some examples, the fan bank 170 can be included in a unified housing with the heat exchanger 140, the manifold 130, or the RPU 160. In some examples, the fan bank 170 can be a removable (e.g., external) module that can be selectively attached to a separate housing for the heat exchanger, the manifold 130, or the RPU 160.

As noted above, some examples can include hot-swappable pump assemblies, including as can be configured as hot-swappable pump cassettes, i.e., self-contained modules that include a pump for an RPU, inlet and outlet connections for the pump (e.g., known types of quick-connect fittings), and a cassette frame that supports the pump for operation within an RPU (and ICD) and also supports the inlet and outlet connections for the pump to be appropriately engaged with corresponding connections for the RPU within the ICD. Correspondingly, in the illustrated example of FIG. 1A, the ICD 120 of the cooling system 100 includes at least one pump cassette 180, which is configured (as shown by block arrow) for hot-swappable installation into or removal from the ICD 120. In the illustrated example, the ICD 120 includes cassette bays for two pump cassettes within the RPU 160 and the ICD 120 can thus receive two substantially identical instances of the pump cassette 180 (e.g., in a side-by-side or stacked configuration) for parallel or redundant operation. In other aspects, other arrangements (e.g., different numbers) of RPUs or of corresponding sub-systems of an ICD (e.g., bays within the ICD for RPUs) are possible.

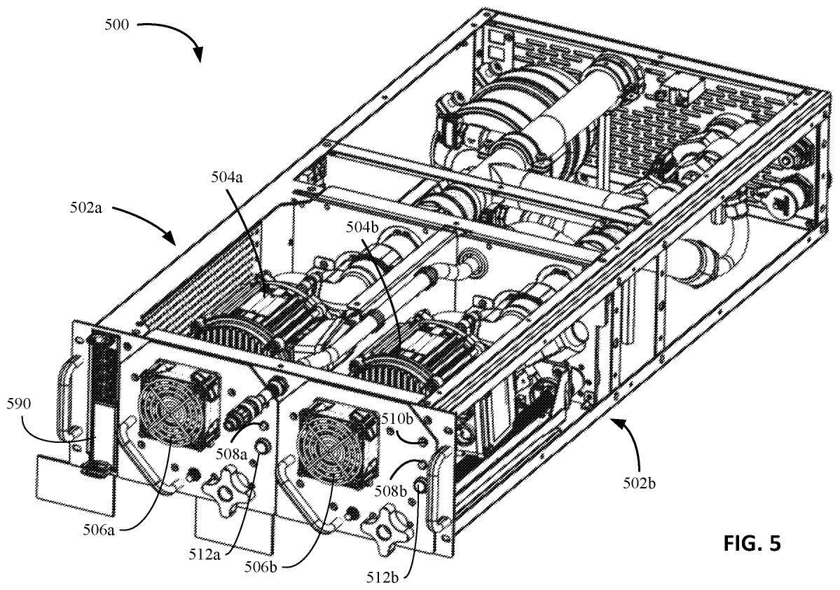

An ICD can include one or more controllers (e.g., one or more master controllers) for controlling operation of electrical components (e.g., pumps, valves, fans, and interfaces of an ICD. For example, a speed of the fans within the fan bank 170 can be controllable to achieve a rate of heat transfer from a liquid to the air (e.g., the controller can implement a proportional integral derivative (PID) controller to achieve a set temperature or temperature differential for a sensed air or coolant temperature of the ICD). In some cases, a controller can operate pumps of an ICD to control a rate of flow through the ICD (e.g., to implement a PID controller). In this regard, FIG. 1A illustrates a controller 190 for the ICS 120. In some examples, the controller 190 for the ICD 120 can be housed on the ICD 120. In some cases, for example, the controller 190 can be housed in a slot of the ICD 120. In some cases, the controller 190 can be housed within the RPU 160 (e.g., as shown in FIG. 5). In some cases, a controller can be a remote controller (e.g., remote relative to the ICD), and can control components of an ICD or an RPU via a wired or wireless connection with the electronic components of the ICD.

FIG. 1B illustrates example arrangements of the ICD 120 and the pump cassette 180 of the RPU 160 to provide hot-swappable pump capacity for cooling operations with the cooling system 100. Only one pump cassette 180 is shown in FIG. 1B for clarity of presentation. As noted above, some implementations can include multiple pump cassettes, including multiple substantially identical (or other) cassettes configured for parallel or redundant operation for cooling operations. In some examples, an RPU can include a single pump cassette.

In the illustrated example, the pump cassette 180 includes a cassette frame 210 that supports a pump 220 and a flow connection module 230 in fluid communication with the pump 220. The flow connection module 230 includes an inlet connection 232 and an outlet connection 234, which are configured to interface with outlet connection 152 and inlet connection 154, respectively, of the connection module 150 of the RPU 160 within the ICD 120. Thus, when installed with the connection modules 232, 152 and 234, 154 engaged, the pump 220 can provide flow for cooling operations of the ICD 120 (e.g., via the manifold 130 as discussed above) and the cooling system 100 as a whole.

In some cases, other connection types can be included in the modules 150, 230 or otherwise. For example, some connection modules for an RPU can include electronic connection modules as can allow electronic communication and power transfer between the RPU and an ICD generally (e.g., for the pump 220, various sensors (not shown in FIGS. 1A and 1B), fan modules of the fan bank 170, one or more controllers on the pump cassette 180 or within the ICD 120, etc.). In some aspects electronic connection modules can permit communication between control systems on an RPU (e.g., a variable frequency drive for the pump 220) and a larger control system of the cooling system 100 (e.g., a programmable electronic controller 190 included in the ICD 120 (see FIG. 1A)).

In different examples, the cassette frame 210 can be differently configured. In some examples, the cassette frame 210 can include a skeletal support structure such as, for example, edge struts to form a rectangular scaffolding to which the pump 220 and the flow connection module 230 can be secured. In some examples, the cassette frame 210 can include a sled (e.g., an enclosed or partly enclosed rectangular box structure) that can support and more extensively shield the pump 220 and the flow connection module 230. For example, the cassette frame 210 can be formed primarily as a bent sheet metal structure with a support floor for the pump 220, one or more side walls, a front wall (e.g., a cover for an included fan to cool the pump 220), etc. In some aspects, a cassette frame 210 can be molded or otherwise formed from plastic or other polymers or composites.

In some cases, the flow connection module 230 can include only the inlet and outlet connection modules 230, 234. For example, the connection modules 230, 234 can be free-floating inlet and outlet fittings or conduits or can otherwise be non-rigidly secured to the cassette frame 210 and the connection modules 230, 234 can then be received and, as appropriate, aligned by corresponding structures of the RPU 160 within the ICD 120. For example, the connection module 150 can include funnels or other tapered structures so that as the cassette is received into the corresponding cassette bay of the RPU 160, the connection module 150 can receive the outlet connection modules 230, 234 with the outlet connection modules 230, 234 within a relatively large range of potential positions (e.g., with a center of either of the connection modules 230, 234 displaced from a nominal centered location by 0.5 times the diameter or greater of the relevant fitting or flow conduit).

In some cases, the connection modules 230, 234 can be secured (e.g., rigidly secured) only to the pump 220 and thus may be only indirectly supported by the cassette frame 210. For example, the pump 220 may be rigidly secured to the cassette frame 210 and the connection modules 230, 234 may extend rigidly from the pump 220, but the connection modules 230, 234 may not be otherwise connected to or supported by the cassette frame 210. In some aspects, correspondingly, the connection modules 230, 234 can be unified with the pump (e.g., part of a pump housing or included pump inlet or outlet structure) rather than included as separate components.

In some cases, the connection module 150 can be non-rigidly secured within the ICD 120. For example, one or both of the connections 152, 154 can be configured to be moved with the pump cassette 180 as the pump cassette 180 is moved into or out of the house (e.g., between an operational position within the ICD 120 and an installation/uninstallation position that is otherwise located inside or at least partly outside the ICD 120).

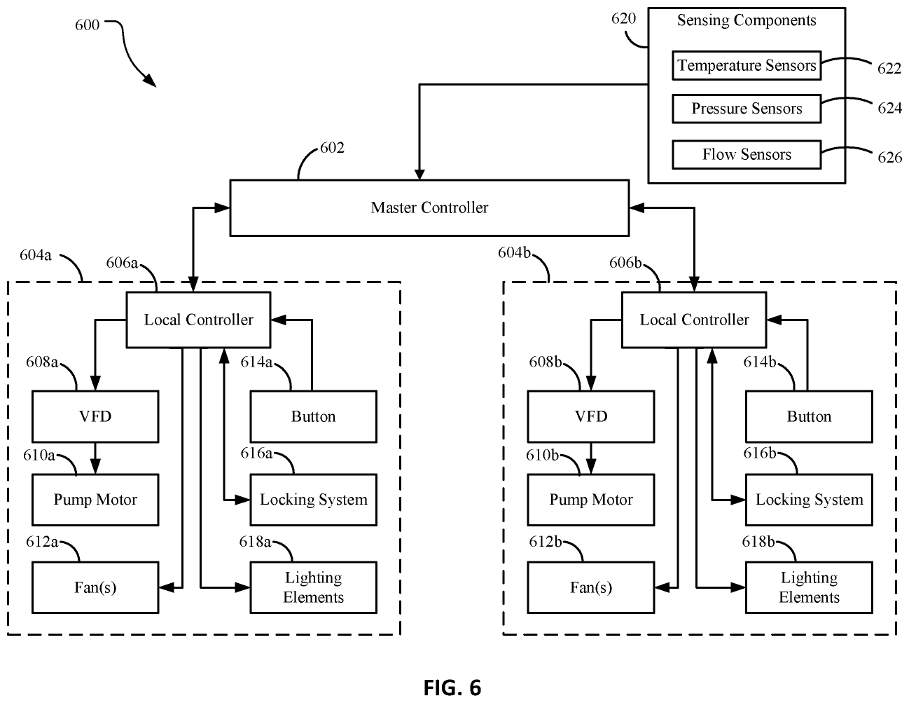

In some examples, a locking system can be included to secure a pump cassette in an installed (or other) position. For example, a locking system (e.g., locking system 616a shown and described with respect to FIG. 6) can secure a pump cassette in an installed position for cooling operations and can also be engaged to actively move the pump cassette into the installed position. A locking system for a pump cassette can operate to lock (e.g., prevent removal of) the pump cassette relative to the RPU. In a preferred embodiment, the locking system is in electrical communication with a controller (e.g., a local controller, a master controller, etc.). In some cases, locking systems for an RPU can include a solenoid or other electromechanical device. Locking systems for RPUs can be in communication with one or more controllers (e.g., one or both of a master controller for an ICD and a local controller for a pump cassette) and can receive commands from the one or more controllers to selectively lock and unlock the pump cassette. In some embodiments, the locking system engages a locking mechanism which may lock or unlock a pump cassette. In some cases, a locking or unlocking operation can be initiated by a user input (e.g., via a button on a pump cassette, an instruction to a controller through a user interface (UI) a command line interface (CLI), an application programming interface (API), or any other interface through which a user can issue an instruction to a controller). In some cases, locking or unlocking a pump via a locking system can be dependent on a condition. For example, before a pump can be unlocked, a controller can confirm that a flow of fluid has been halted at the pump, as can prevent leakage of fluid upon removal of the pump cassette.

In some aspects, a locking system can be arranged to be readily accessed by authorized users from outside an ICD. For example, as shown in FIG. 1B, a locking system for the RPU 160 can include an ICD locking structure 112 and the pump cassette 180 can include a locking structure 186 configured to lockingly engage with the locking structure 112 to secure the pump cassette 180 within the ICD 120 for cooling operations.

In different examples, a variety of locking structures can be used, including: latch or bolt systems, rotary or linear cam systems, spring-biased catches or other structures, electronic or magnetic systems, manually or automatically actuated systems, etc. Thus, for example, the locking structure 186 of the pump cassette 180 can include a rotary cam, spring-biased or lever-operated latch, or other similar extendable/retractable structure, and the locking structure 112 of the RPU 160 in the ICD 120 (or the ICD 120 generally) can include a corresponding recess, protrusion, or other structure that can lockingly engage with the locking structure 186 of the pump cassette 180, or vice versa. In some examples, as also generally noted above, engagement of such a rotary cam, latch, or other structure on the locking structure 186 with the locking structure 112 can help to urge the pump cassette 180 into a final installed orientation (e.g., via linearized force of a rotating spiral cam or lever mechanism).

In some aspects, engagement of relevant locking structures or other similar installation steps can result in enabling or other signals for operation a control system of the ICD 120 and the cooling system 100 generally (e.g., a pump drive, fan drive, or general purpose industrial controller of various known types (not shown)). For example, operation of the pump 220 may not be permitted in some examples until a switch or other sensor (not shown) of known or other configurations is activated to indicate proper engagement of the connection modules 150, 230, proper alignment of the pump cassette 180 overall, or one or more of other satisfactory diagnostic states.

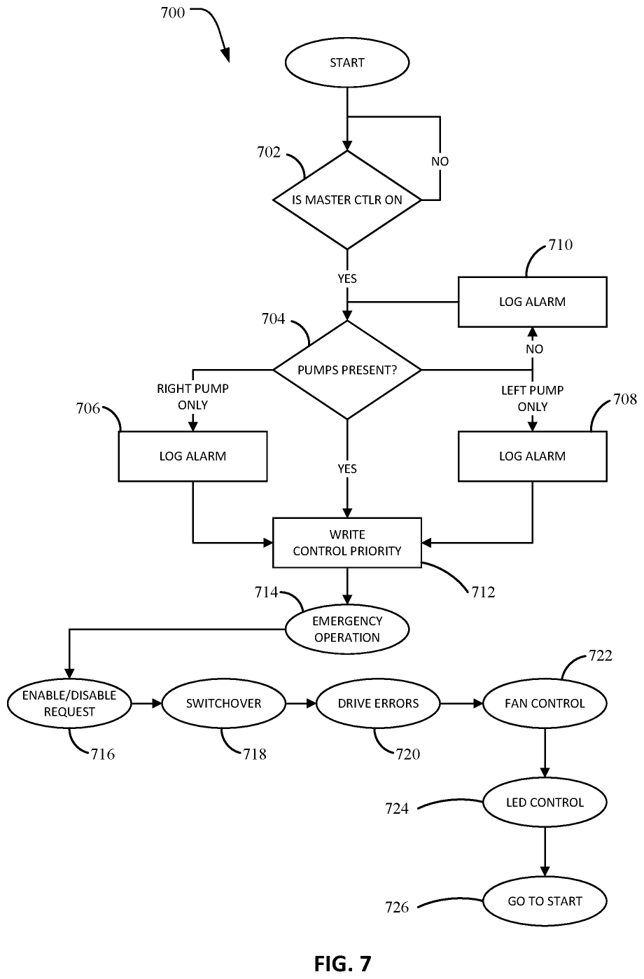

Various other examples of RPUs and related systems are presented below. Unless otherwise indicated, use of similar reference numbers for similarly named components in different examples (e.g., the RPU 180 and an RPU 180A) indicates similar possible structures and functionality for the discussed components. Thus, for example discussion of the cooling system 100 herein generally also applies—at system and component levels—to other cooling systems 100A, 100B, etc. While the aspect of FIGS. 1A and 1B illustrates the RPU 180 installed in an ICD, RPUs, according to this disclosure can be installed in other configurations. For example, an RPU can be installed in a cabinet of server equipment (e.g., as opposed to being installed in an ICD), and can operate to induce a flow of liquid coolant to servers within the corresponding cabinet (e.g., to servers or other electrical equipment in the rack). RPUs installed in racks of electrical equipment can increase a modularity of a liquid cooling system (e.g., liquid-to-air, air-to-liquid, or liquid-to-liquid cooling systems), as the RPU can increase a flow capacity along the cooling system to prevent a pressure drop on the addition of racks of electrical equipment in a row of a data center. The systems (e.g., system 600 shown in FIG. 6) and processes (e.g., processes 700, 800, 900, 1000, 1100, 1200, 1300, and 1400 described below with respect to FIGS. 7-14) can be applicable to RPUs installed in racks having any configuration (e.g., racks having the arrangement of components described with respect to FIGS. 1A and 1B, or racks including servers, network equipment, storage disks, etc.).

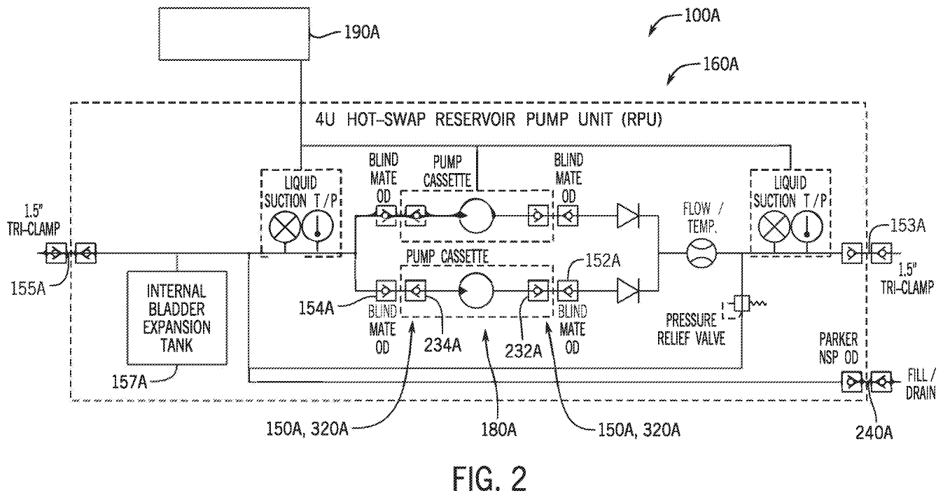

FIG. 2 illustrates aspects of an RPU 180A that can be implemented as an example of the RPU 180 (e.g., as discussed above) in a cooling system 100A that is an example of the cooling system 100 (e.g., as discussed above). In particular, the RPU 160A includes two pump cassettes 180A (only one numbered) with blind mate liquid connections 150A, 320A (e.g., with quick-connect inlet fittings 234A, 154A and quick-connect outlet fittings 232A, 152A) so as to be easily installed into or removed from the RPU 160A. As generally discussed relative to the RPU 160, the pump cassettes 180A of the RPU 160A are arranged to operate in parallel with each other to provide pumped cooling flow from an upstream inlet of the RPU 160A to a downstream outlet of the RPU 160A. Other components can also be included in some cases, including various flow equipment (e.g., an expansion tank as shown to accommodate for thermal expansion and other volume fluctuations), and one or more flow sensor packages (e.g., for suction and supply temperature and pressure for the pump cassettes 180A). An electronic controller 190A can also be included (e.g., as part of or in communication with a variable frequency or other drive for the pumps of the pump cassettes 180A), and appropriate communication channels (e.g., for wired communication) can be provided between the controller 190A, the sensors, the pump cassettes 180A (e.g., via quick-connect electrical connections (not shown)), fans of an ICD external to the RPU 160A etc. Although shown separately in FIG. 2 (e.g., as may be included within the ICD 120 of FIG. 1A or other associated system), the controller 190A can be partly or fully included on the RPU 160A in some cases.

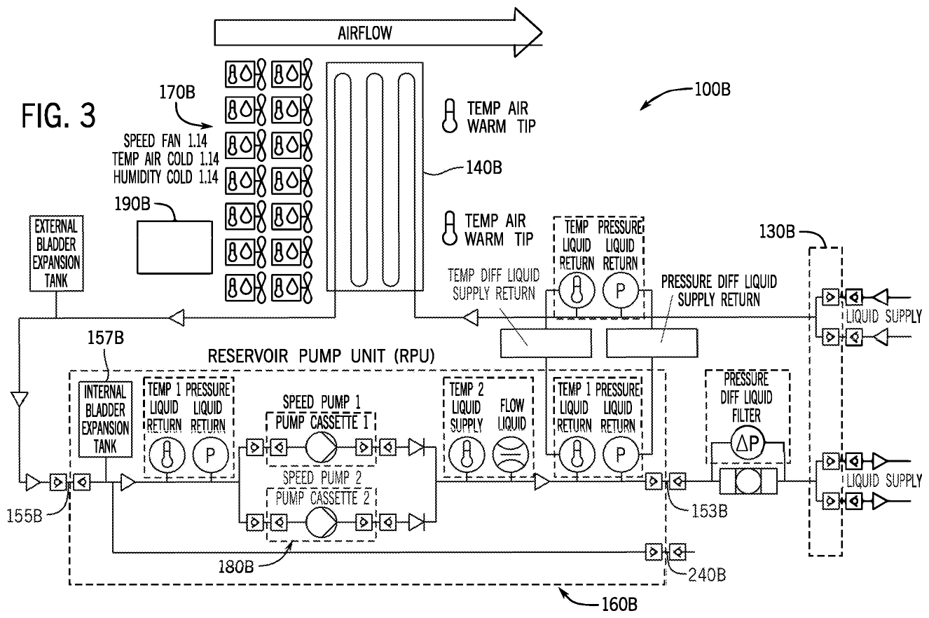

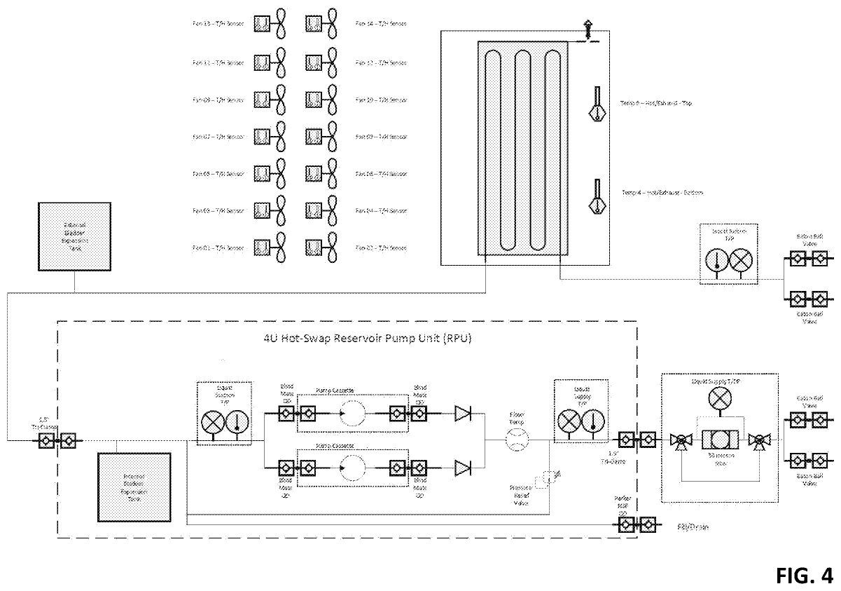

FIG. 3 illustrates aspects of a cooling system 100B that can be implemented as an example of the cooling system 100 discussed above. In particular as shown, the cooling system 100B includes an RPU 160B that is generally similar to the RPU 160A discussed above (see, e.g., FIG. 2), with additional sensor capabilities (e.g., with additional temperature and flow sensors relative to the RPU 160A). The cooling system 100B can accordingly implement cooling operations as similarly discussed above, with pump cassettes of the RPU 160B providing pumping power to distribute cooled fluid to one or more external (or other) electronic systems to be cooled through a liquid supply and to receive heated fluid from the one or more electronic systems through a liquid return (e.g., as both included in a manifold 130B), as well as to move the heated fluid through a heat exchanger 140B to be cooled by a fan bank 170B. Correspondingly, various operations of the cooling system 100B can be controlled by an electronic controller 190B, including as may coordinate pump speed and fan speed based on data from the various illustrated (or other) sensors. FIG. 4 illustrates aspects of a similar cooling system as the cooling system 100B, with certain modifications (e.g., with a bypass loop for the supply-side filter, upstream of the RPU, generally, and the pump cassettes in particular).

FIG. 5 shows aspects of an RPU 500 that can be implemented as an example of the RPU 160 (e.g., as discussed above). In some examples, the RPU 500 can be installed in an ICS (e.g., ICD 120, shown in FIG. 1). In some examples, the RPU 500 can be installed in any rack within a data center to providing pumping capacity for liquid cooling systems with components distributed between multiple racks (e.g., with heat exchangers, manifolds, fans, etc. positioned along a cooling circuit in multiple racks). In the illustrated example, the RPU 500 includes a set of two substantially identical pump cassettes 502a, 502b, each of which include a cassette frame that supports a pump 504a, 504b and associated drive motor and cooling fan 506a, 506b and also supports a flow connection module with an inlet connection and an outlet connection. A pump cassette can include any number of peripheral electronic devices, including, for example, fans, LEDs, audio indicators, and/or something as described below.

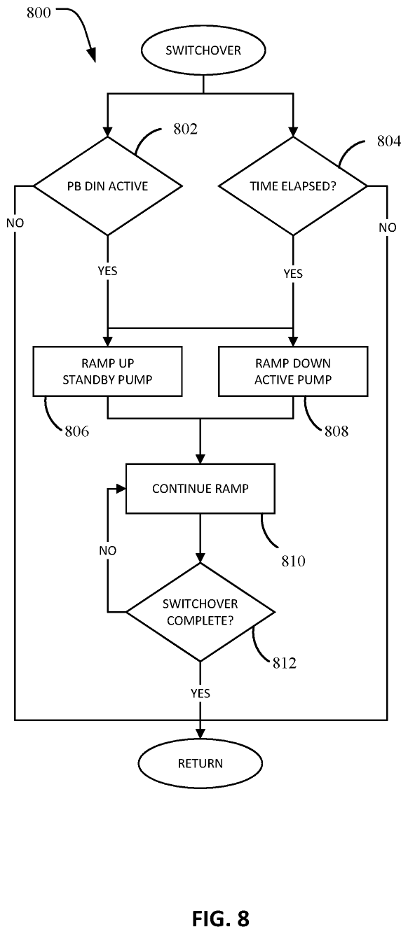

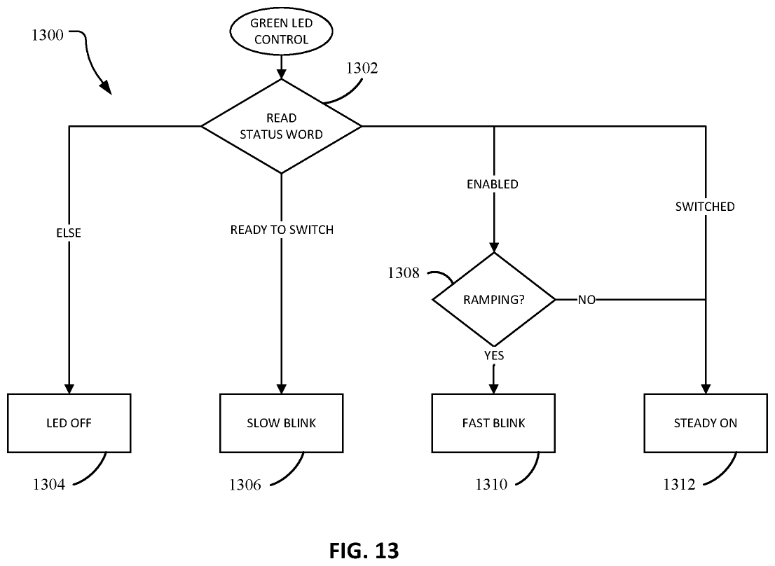

Each pump cassette 502a, 502b can further include indicators and inputs for operators of the RPU to communicate a status of the RPU to an operator, and to allow an operator to control an operation of the RPU respectively. For example, as further shown in FIG. 5, the pump cassettes can include a first LED 508, a second LED 510, and a power button 512. In other aspects, a pump cassette can include additional indicators including, for example, additional visual indicators (e.g., lights, LEDS, flags, etc.) or audio indicators (e.g., a speaker). In some aspects, a number of LEDs can be different than shown, and a pump cassette can include only 1 LED, no LEDs, or more than 2 LEDs. In the illustrated example, the first LED 508 is a red fault status LED, and the second LED 510 is a green operational status LED. As described below with respect to FIG. 13, the first lead 508 can indicate an alarm state or a fault of the pump cassette 502, and the second LED 510 can indicate an operational state (e.g., an operating mode) of the pump cassette 502. LEDs of a pump cassette can be controlled to turn on, turn off, or blink at different frequencies to communicate different states of the respective pump cassette 502a, 502b, or components thereof (e.g., fan 506, pump 504, a controller, a connectivity to a master controller, etc.). In some cases, the power button 512 can at least partially determine an operational state of the pump 504 of the corresponding pump cassette 502. For example, in a normal operation of the RPU 500 (e.g., when a local controller of the pump cassette 506 is in communication with a master controller), engagement of the power button 512 can initiate a switchover procedure for the pumps, to change an operation of the pump 504 of the corresponding cassette, as further described with respect to FIG. 8. Further, additional buttons or inputs can be provided to allow a user to control aspects or components of the individual pump cassette 502a, 502b.

RPUs for cooling systems can further include control units to control an operation of the RPU and other components of a cooling system. For example, as further illustrated in FIG. 5, the RPU can include a removable controller 590. The removable controller 590 can be received into a controller slot of the RPU 500 and can be configured for toolless removal and replacement by an operator of the RPU 500. The removable controller 590 can be a master controller for controlling operation of the pumps and other electronic components of the pump cassettes 502a, 502b (e.g., fans 506, LEDs 508, 510, locking systems, etc.). Further, the removable controller 590 can be hot swappable, and components of the RPU 500 can be configured to operate in an emergency mode when communication with the removable controller 590 and control systems of the pump cassettes 502a, 502b is lost (e.g., when the controller 590 is removed for servicing, or when a local controller for a pump cassette 502a, 502b otherwise determines that a communication with the master controller 590 is lost). In some cases, an RPU can include multiple removable controllers in a redundant configuration (e.g., the controllers can be configured in an active-active, active-passive, or failover modes). In some cases, an RPU can include multiple controllers, each controller having a specialized function (e.g., one controller can provide interfaces for users, with another controller implementing control systems for pumps of an RPU). In some cases, a master controller in communication with local controllers of pump cassettes of an RPU is remote with respect to the RPU. For example, a controller can be housed in top of a rack, can be implemented by a server within a rack, can be remote to the data center, etc.

Flow connection modules for an RPU (e.g., flow connection module 230 shown in FIG. 1B) can generally include known types of quick-connect fittings or other connection structures as generally described above and can be supported by the cassette frame to be appropriately aligned for engagement with corresponding connection modules on the ICD 120C (not shown). Electrical connections (e.g., electrical quick-connect connections of various known types) can also be provided, including as can provide power or control signals for the pumps 504 (e.g., for variable frequency drives to control pump speed), and other electrical components of the pump cassette (e.g., fans 506, LEDs 508, 510, solenoids for locking systems, controllers 590, etc.).

FIG. 6 is a schematic illustration of a control system 600 for liquid cooling systems including an RPU (e.g., any of the cooling systems and RPUs illustrated in FIGS. 1-5). As shown, the system can include a master controller 602 (e.g., the controller 190 shown in FIG. 1A, the removable controller 590 shown in FIG. 5, etc.), sensing components 620, and local controllers 606a, 606b of pump cassettes 604a, 604b respectively (e.g., similar to pump cassettes 502a, 502b). In some aspects, the local controllers 606a, 606b may be local controllers. In some aspects, more or fewer pump cassettes can be included in the control system for cooling system. The master controller 602 can be in communication with the sensing components 620 and the local controllers 606a, 606b to control flow parameters of the cooling system, as detailed below. In some cases, the master controller 602 can control components of a cooling system external to the RPU, including, for example, fans of a fan bank of an ICD (e.g., fans of fan bank 170 shown in FIG. 1A).

Each local controller 606a, 606b can further be connected to electrical components of the respective pump cassette 604a, 604b. Electrical components of a pump cassette can include or more peripheral electronic devices (e.g., fans, speakers, LEDs, digital outputs, audio devices, etc.) controllable by the local controller and may include input elements to allow user to dictate operation. For example, as further shown in FIG. 6, each pump cassette 604 can include a variable frequency drive (“VFD”) 608, connected to a pump motor 610 (e.g., pump motors for pumps 504a, 504b shown in FIG. 5), the VFD 608 being configured to generate a signal to the pump motor 610 to control a speed of the pump motor 610, and thereby a flow of fluid through the pump cassette 604. The pump cassette further includes a fan 612 (e.g., fan 506a, 506b shown in FIG. 5) for cooling electrical components of the pump cassette 604, a power button 614 (e.g., power button 512a, 512b shown in FIG. 5), a locking system 616, and lighting elements 618 (e.g., LEDs 508 and 510 shown in FIG. 5). The locking system 616 can include a solenoid and a limit switch and can receive a control signal from the master controller 606a (e.g., the master controller 602 can communicate an instruction to the local controller 606a, and the local controller 606a can issue a corresponding signal to the locking system 616a) to retain the pump cassette 604 in a locked configuration or to unlock the pump cassette 604. Operation of other components (e.g., the motor 610 and fan 612) can be dependent on the pump cassette 604 being in the locked configuration. The local controller 606a can be connected to each of the VFD 608, fan 612, lighting elements 618, and locking system 616 to operatively control each of the electrical elements and can further receive inputs from the locking system 616 and the power button 614.

The local controllers 606a, 606b can be connected to the master controller 602 through a wired connection and can receive operating instructions from the master controller 602 for controlling electrical elements of the respective pump cassette 604a, 604b. The connection between the master controller 602 and each of the local controllers 606a, 606b can be a connection using Modbus protocols for communication between the local controllers 606a, 606b and the master controller 602 (i.e., the master controller 602 can be a Modbus server, and the local controllers 606a, 606b can be Modbus clients). In some embodiments, the master controller 602 can send a speed instruction to the local controller 606a, 606b. In other embodiments, the master controller may instruct the local controller 606a, 606b to operate in a plurality of operating modes. In some aspects, the master controller 602 can issue instructions to the local controllers 606a, 606b to implements a PID control method to achieve set points for any operating parameter sensed by sensing components 620. For example, the sensing components 620 can include temperature sensors 622, pressure sensors 624, and flow sensors 626. Each of the respective sensors can provide a signal to the master controller 602, and the master controller 602 can issue a signal to the local controller 606a, 606b to adjust a speed of the pump motors 610a, 610b thereby adjusting a flow of fluid through the respective pump cassette to achieve the desired set point for the operating parameter. Sensing components 620 can include sensors housed in pump cassettes, sensors of an ICD in which the RPU is housed, sensors for sensing ambient parameters for an environment of a cooling loop (e.g., ambient temperature sensors, ambient pressure sensors, ambient humidity sensors, etc.), or sensors sensing parameters along a cooling loop external to the ICD (e.g., temperature sensors for temperatures of electrical equipment to be cooled, fluid pressure at manifolds of a rack, fluid temperature at racks along the cooling loop, etc.). In some aspects, the master controller 602 can implement a PID control method for the fan 612, and can provide instructions to the local controller 606a, 606b to control a speed of the respective fan 612a, 612b to achieve a set point for a given operating parameter (e.g., to achieve a temperature, flow, or pressure as sensed by sensors 622, 624, and 626 respectively). In other aspects, PID controllers can be implemented by the master controller to achieve set points for other parameters, such as differential pressures, differential temperatures, etc.

In some aspects, each local controller 606 is a programmable logic controller (PLC). In some aspects, the local controller 606 can include a processor, one or more inputs (e.g., for receiving signals from the power button 614 or a switch of the locking system 616), outputs (e.g., ports and interfaces for controlling the VFD 608, fan 612, and lighting elements 618) and a memory. In some aspects, processors for the local controllers 606 can be any suitable hardware processor or combination of processors, such as a central processing unit (CPU), a graphics processing unit (GPU), an application specific integrated circuit (ASIC), a field-programmable gate array (FPGA), etc.

In some aspects, a memory for the local controller 606 can include any suitable storage device or devices that can be used to store instructions, values, etc., that can be used, for example, by the processor of the local controller to implement control loops and algorithms of the cooling system 600, to store logs of the controller 606, etc. The memory can include any suitable volatile memory, non-volatile memory, storage, or any suitable combination thereof. For example, the memory can include random access memory (RAM), read-only memory (ROM), electronically-erasable programmable read-only memory (EEPROM), one or more flash drives, one or more hard disks, one or more solid state drives, one or more optical drives, etc. In some aspects, memory can have encoded thereon a computer program for controlling operation of the controller 606. For example, in such aspects, a processor can execute at least a portion of the computer program to receive inputs and implement control loops in response. The memory can store variables thereon for controlling operation of the electrical components controlled by the controller 606 (e.g., the VFD, locking system 616, lighting elements 618, and fans 612). For example, the memory can store thereon a priority variable specifying a priority of the local controller 606 (e.g., whether the local controller 606 is operating autonomously, or if it is receiving instructions from the master controller 602). Other variables can be stored on the memory to control other aspects of an operation of the local controller 606 (e.g., whether a pump is enabled, whether a solenoid is operational, whether a pump is active, a target speed of the pumps, a preset target speed of the pumps, etc.). In some aspects, the memory can store firmware thereon including algorithms and processes for controlling the electrical components of a pump cassette 604. In some aspects, the firmware of the controller 606 can only be updated over a direct wired connection to the controller at a physical interface thereof, as can provide enhanced security for operational aspects of the local controller 606 and electrical components controlled thereby.

In some examples, a memory of the local controllers (e.g., local controller 606a shown in FIG. 6) can have stored thereon tables including variables of the local controller at predetermined addresses (e.g., rows) of the table. In some cases, tables of the local controller including variables can be configured to be usable with Modbus communications protocols. For example, the memory of the local controller can include a “Coils” table, which can include variables having one-bit values (e.g., the variables of the Coils table can have only one of two values). The variable values in the Coils table can be readable and writable by a master controller in communication with the local controller (e.g., master controller 602 can read or write values to variables stored at the Coils table in a memory of local controller 606a). Each variable can be associated with a logic address, and the master controller can specify the logic address of the variable to be read or written to. In this regard, Table 1 below illustrates an example Coils table, including logic addresses for a control priority variable and a “ready to switch on” variable, which, as shown, can each be one of “0” or “1.” The logic addresses and function codes are provided for illustration only, and variables of a Coils table can be addressed at different locations and correspond to different function codes. Further, a Coils table (e.g., or other table in a memory of a local controller including 1-bit values for variables that are readable and writable by a master controller) can include additional variables corresponding to other parameters of a local controller.

TABLE 1
Coils Table

| Logic | Function | | |
|---|---|---|---|
| Address | Code | Content | Description |
| 18 | DRF2 | Ready to | Configures the default behavior of the |
| | | switch on | DS402 state machine upon power up of |
| | | is reached | the local controller. |
| | | at start up | Value: |
| | | | “0” = Ready to switch on is not reached |
| | | | “1” = Ready to switch on is reached |
| | | | upon power up |
| 19 | DRF3 | Control | Changes who has control over the drive |
| | | Priority | “0” = local control |
| | | | “1” = Modbus control |

In some cases, a memory of a local controller (e.g., local controller 606a) can include a table having values corresponding to actual states of elements of the corresponding pump cassette (e.g., variables including states for components of pump cassette 604a, including VFD 608a, pump motor 610a, fans 612a, the button 614a, locking system 616a and associated solenoids and limit switches, lighting elements 618a, etc.). A table indicating values of actual states of the system can be readable by the master controller, but may not allow a write operation from the master controller, as can advantageously allow the table to reflect an actual system state. In some cases, the table can be an “Input Register” table, and can adhere to Modbus standards for integration with systems using Modbus protocols. An “Input Registers” table can include variables with values represented as 16-bit integers (e.g., also referred to as “words”), as can advantageously allow a variable within the table to represent multiple possible states or values (e.g., beyond the two values allowed by a 1-bit variable). In this regard, Table 2 illustrates an example “Input Registers” table, including variables that can be used with the systems and processes described herein. In some examples, an Input Registers table can include more or fewer variables (e.g., table entries). In some cases, state variables of a system can be stored in memory as variables (e.g., as opposed to entries in a table).

TABLE 2
Input Registers

| Address | Content | Code | Description |
|---|---|---|---|
| 26 | Status | SW1 | Actual state of the DS402 state machine. |
| | word | | Range: 0 TO MAX |
| | | | Values: |
| | | | “xxxx xxxx x0xx 0000” = Not ready to |
| | | | switch on |
| | | | “xxxx xxxx x1xx 0000” = Switch on |
| | | | disabled |
| | | | “xxxx xxxx x01x 0001” = Ready to |
| | | | switch on |
| | | | “xxxx xxxx x01x 0011” = Switched |
| | | | on |
| | | | “xxxx xxxx x01x 0111” = Operation |
| | | | enabled |
| | | | “xxxx xxxx x00x 0111” = Quick stop |
| | | | active |
| | | | “xxxx xxxx x0xx 1111” = Fault reaction |
| | | | active |
| | | | “xxxx xxxx x0xx 1000” = Fault |
| | | | Bit 11 of the status word signals the target |
| | | | reached (FBFF mask) |
| 29 | Digital | | Actual state of the physical discrete inputs. |
| | input | | Range: 0 TO MAX |
| | status | | Values: |
| | | | Bit 0: state of digital input 1 |
| | | | Bit 1: state of digital input 2 |
| | | | Bit 2: state of digital input 3 |
| | | | Bit 3: state of digital input 4 |
| | | | Bit 4: state of the enable |
| 32 | Boot | | UNS16 |
| | address | | |
| | register | | |
| 97 | Error | | UNS16 |
| | code 8 | | |
| 111 | Polarity | FS13 | Defines the polarity applied to the motor |
| | | | poles. |
| | | | Defines the speed of the motor rotation. |
| | | | (UNS16) |
| | | | Range: 0 to 65536 |
| 116 | Torque | MV1 | Actual torque in ‰ of rated torque (S16) |
| | actual | | Range: −10000 TO 10000 |
| | value | | |

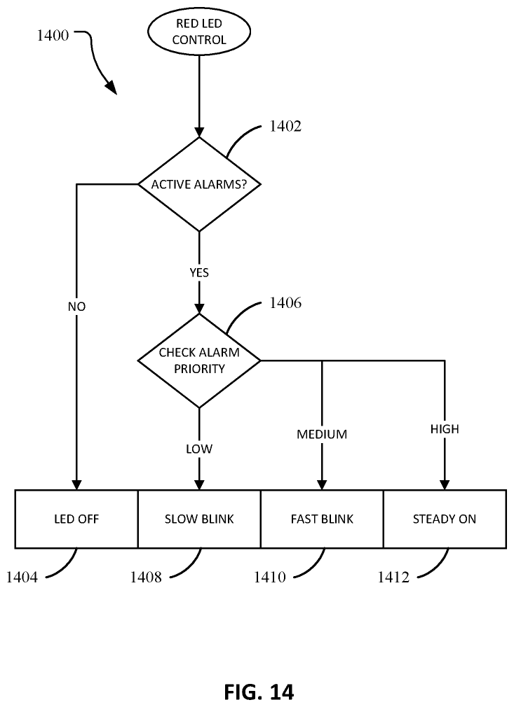

In some cases, a memory of a local controller (e.g., local controller 606a) can include a table having values corresponding to desired states of elements of the corresponding pump cassette (e.g., variables including desired states for components of pump cassette 604a, including VFD 608a, pump motor 610a, fans 612a, the button 614a, locking system 616a and associated solenoids and limit switches, lighting elements 618a, etc.). A table indicating values of desired states of the system can be readable and writable by the master controller, and a master controller can control an operation of a local controller and components controlled by the local controller by setting state variables to a desired value. In some cases, the table can be an “Holding Register” table, and can adhere to Modbus standards for integration with systems using Modbus protocols. An “Holding Registers” table can include variables with values represented as 16-bit integers (e.g., also referred to as “words”), as can advantageously allow a variable within the table to represent multiple possible states or values (e.g., beyond the two values allowed by a 1-bit variable). In this regard, Table 3 illustrates an example “Holding Registers” table, including variables that can be used with the systems and processes described herein. In some examples, a Holding Registers table can include more or fewer variables (e.g., table entries). In some cases, state variables of a system can be stored in memory as variables (e.g., as opposed to entries in a table). As shown below, a Holding Registers table can include gain parameters, maximum and minimum values, and set points for PID control processes to be implemented by the local controller. The table can further include operator-configurable parameters defining an operation of the local controller and associated pump cassette. For example, a holding registers table can include variables defining the behavior of LEDs of a pump cassette (e.g., can control a blinking or on/off state of LEDs 508a, 510a shown in FIG. 5), as described further with respect to FIG. 13 and FIG. 14.

TABLE 3
Holding Registers

| Address | Content | Code | NVM | Description |
|---|---|---|---|---|
| 34 to | KP speed | SP1 | Yes | KP parameter of speed PID (FLOAT) |
| 35 | PID | | | Range: FULL |
| | | | | Setting: |
| 36 to | KI speed | SP2 | Yes | KI parameter of speed PID (FLOAT) |
| 37 | PID | | | Range: FULL |
| | | | | Setting: |
| 38 to | KD speed | SP3 | Yes | KD parameter of speed PID (FLOAT) |
| 39 | PID | | | Range: FULL |
| | | | | Setting: |
| 85 to | Max motor | SF1 | Yes | Maximum motor speed possible (UNS32) |
| 86 | speed | | | Range: 0 TO MAX |
| | | | | Setting: |
| | | | | “6000” = default value for the application |
| 156 | Control | CM1 | Yes | The control word moves the DS402 state machine from |
| | word | | | one state to another, which must be run through to |
| | | | | enable the power stage. |
| | | | | (UNS8) |
| | | | | Range: 0 TO MAX |
| | | | | Setting: |
| | | | | “6” = SHUTDOWN_CODE |
| | | | | “7” = SWITCHON_CODE |
| | | | | “15” = SWITCHON_ENABLEOP_CODE |
| | | | | “0” = DISABLE_VOLTAGE_CODE |
| | | | | “2” = QUICK_STOP_CODE |
| | | | | “7” = DISABLE_OP_CODE |
| | | | | “15” = ENABLE_OP_CODE |
| 158 to | Target | CM4 | Yes | Velocity set point |
| 159 | velocity | | | Speed limits will be the lower of either ‘Max motor speed’ |
| | | | | or ‘Max profile velocity’. |
| | | | | Range: 0 TO Speed limits (see above) |
| | | | | Setting: |
| | | | | “0” = default |
| 160 to | Green LED | | No | “0” = Off, default |
| 161 | state | | | “1” = Blinking slow-1 Hz-passive (standby) mode, not |
| | | | | operating |
| | | | | “2” = Blinking fast-4 Hz-change-over mode, ramping |
| | | | | “3” to “65535” = steady on-active mode, operating |
| 162 to | Red LED | | No | “0” = Off, default |
| 163 | state | | | “1” = Blinking slow-1 Hz-active alarm, operational |
| | | | | “2” = Blinking fast-4 Hz-active alarm condition, no |
| | | | | communication |
| | | | | “3” to “65535” = steady on-active alarm condition, not |
| | | | | operational |
| 163 to | Modbus | | Yes | “0 to 65535” = Modbus Dead time 0 to 65535 (unit: |
| 164 | Dead Time | | | second) |
| | | | | “30” = default |

FIG. 7 is a flowchart illustrating a process 700 for controlling pumps and other electronic components of an RPU (e.g., LEDS 508, 510 and fans 506 shown in FIG. 5, and VFDs 608, pump motors 610, fans 612, lighting elements 618, and locking systems 616 shown in FIG. 6), according to some aspects. In some aspects, the process 700 can be performed at a master controller of a cooling system (e.g., master controller 602 shown in FIG. 6, removable controller 590 shown in FIG. 5, and controller 190 shown in FIG. 1A). The process begins when the master controller is powered on. In the aspect depicted in FIG. 7, the status of the master controller is checked in a block 702.

In some aspects, when the process 700 determines that the master controller is on, the process 700 can proceeds to check a status of the pumps at block 704 (e.g., the pumps 504 shown in FIG. 5). Checking a status of the pumps can include checking a connectivity to the local controllers (e.g., local controllers 606 shown in FIG. 6) through a Modbus connection to local controllers corresponding to the respective pumps and pump cassettes (e.g., the local controllers 606a, 606b shown in FIG. 6). In some cases, checking a status of the pumps at block 704 can include a communication initiated from the master controller (e.g., the master controller can “ping” the local controllers at a known address). In some cases, when a local controller is powered on, it can “advertise” its presence to the master controller (e.g., the local controller can initiate a communication to the master controller). If no pumps are connected, the master controller can log an alarm at block 710 indicating the absence of pumps. In some aspects, the master controller may log the alarm at a block 710 if no pumps are present. The error code logged at block 710 may be any alpha numerical value designated to indicate an absence of a pump (e.g., an alarm id “E109,” a message indicated the absence of a pump, a standardized log entry or SNMP alert indicating the absence of a pump, etc.). If only the left pump is present (e.g., the master controller can communication with the local controller of the left pump cassette, which can be pump cassette 502a shown in FIG. 5), an alarm can be logged at block 708, with an indication that only the left pump is present. Similarly, at block 706, if only a right pump is present, the process 700 can log an alarm indicating that only the right pump is present. In some cases, logging an alarm can include writing an error message to a log entry of the system. In some cases, logging an alarm can include issuing a notification (e.g., a remote notification at a web interface, a text message, an alert in an application, an email communication, etc.) to an operator of a status of the respective pumps of the RPU.

At block 712, the master controller can write a control priority to the local controllers. A control priority can be a variable on a local controller (e.g., a variable stored in a memory of a local controller) indicating whether the local controller is operating autonomously, or if the local controller is operating as a slave controller, receiving instructions from the master controller. At block 712, in some aspects, the control priority can be written to each of the pumps detected at the block 704 (e.g., the control priority can be set to the master controller upon an established connection between the master controller and the local controller). If only one pump is detected, the process can a control priority for the detected pump, indicating that the master controller has priority. For example, if only the right pump is present, at a block 706, a log alarm may be generated at block 706 and the control priority at the local controller for the right pump can be written to the master controller at block 712. A variable for the control priority can be a variable stored in a memory of the local controller (e.g., local controllers 606a, 606b shown in FIG. 6). In some aspects, the control priority can be a value of 1 or 0, with 1 indicating that the master controller takes priority (e.g., the local controller receives instructions from the master controller for operating electrical components of the pump cassette), and 0 indicating that the local controller takes priority for issuing instructions to the electrical components of the pump cassette (i.e., the local controller is operating autonomously). If both pumps are present, no alarm is generated, and the control priority for each local controller is set to 1, so that the master controller issues instructions to the local controller for control of electrical components of each of the pump cassettes. In some aspects, the control priority is represented as a variable “XYZ,” or some other variation of characters. In some aspects, a control priority variable can be a Boolean type variable. In some aspects, the control priority is automatically set by the local controller upon detecting a connection to the master controller. In some aspects, the control priority is set in response to an instruction issued from the master controller. As discussed further below, the control priority can be set to autonomous control by default, and this can be overwritten when communication is established between the local controller and the master controller.

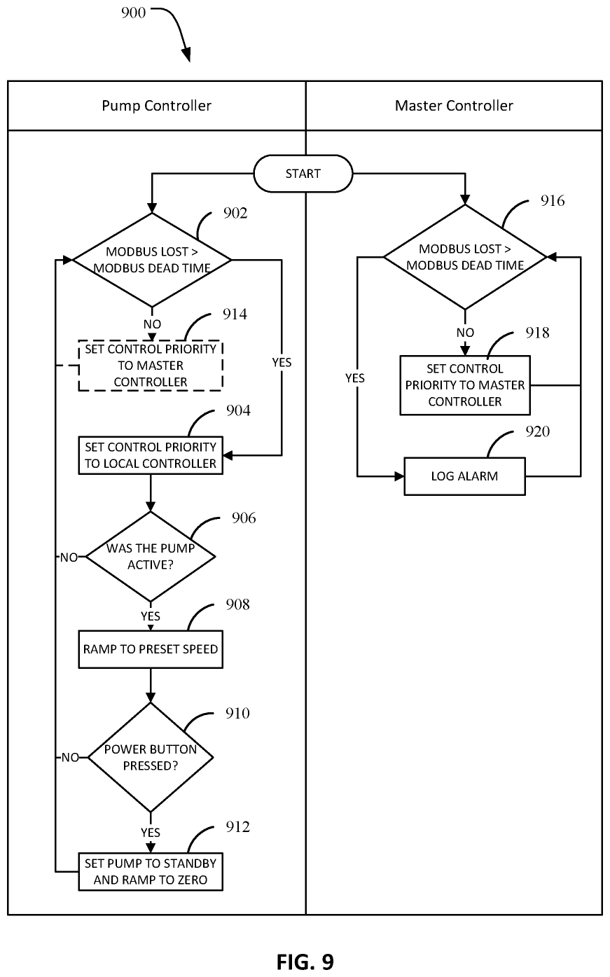

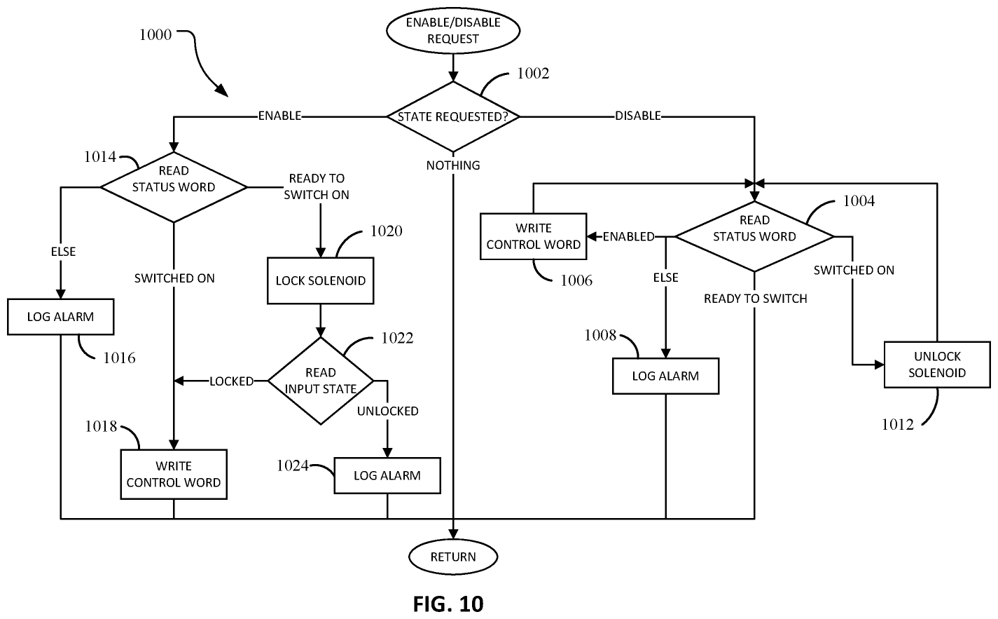

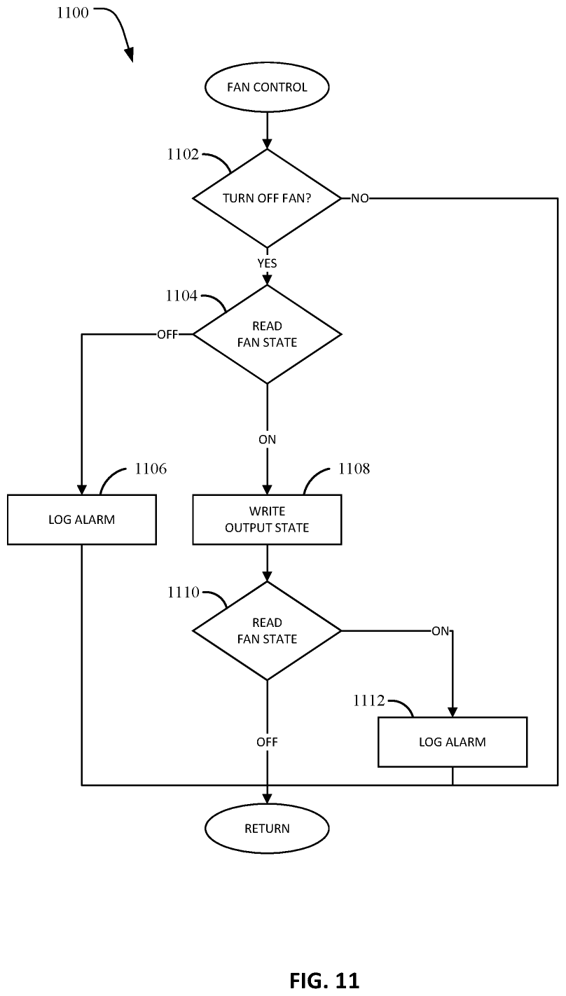

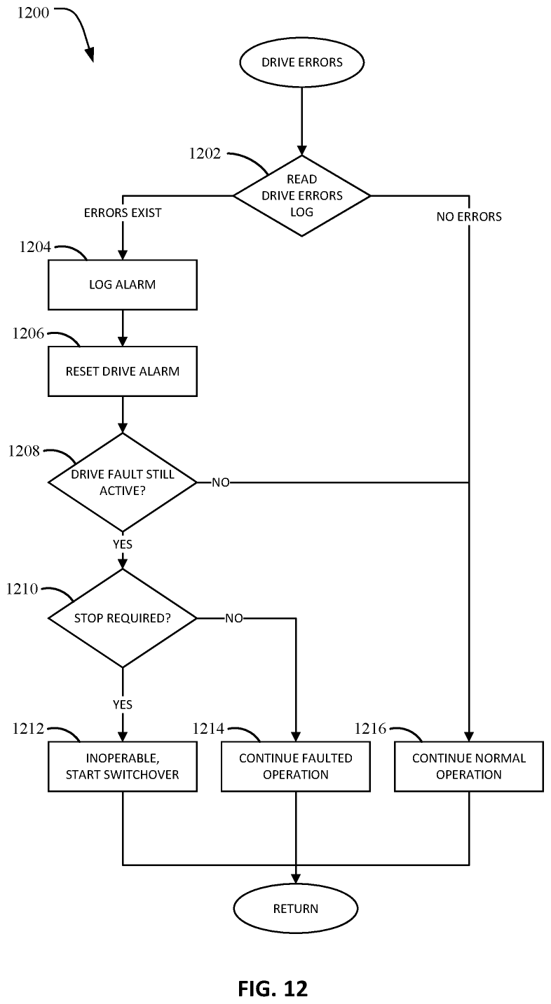

The process 700 can proceed to implement processes for various aspects of operations of the cooling system. In some aspects, the process can implement processes for performing switchover between pumps of an RPU (e.g., as shown in FIG. 8), an emergency operation process for controlling pumps of the CDU when connection is lost between a local controller and the master controller (e.g., as shown in FIG. 9), a process for enabling or disabling a pump (e.g., as shown in FIG. 10), a process for controlling fans (e.g., fans 506 shown in FIG. 5) of pump cassettes (e.g., the process shown in FIG. 11), a process for handling drive errors (e.g., as shown in FIG. 12), and a process for controlling LEDs (e.g., the process shown in FIG. 13 for controlling LEDs 508, 510 shown in FIG. 5). For example, in FIG. 7, at a block 714, an emergency operation process may begin. Further, at a block 716, a process for enabling or disabling a pump may begin. Still further, at a block 718, a switchover process may be initiated to switch between pumps. At a block 720, a process for checking for drive errors may be initiated, which may be followed by a block 722 that controls fans. Next, at a block 724, a process for controlling LEDs may occur, which may be accompanied with a block 726, which restarts the process 700. In some aspects, the order of blocks 714 through 724 may be reordered. For example, block 716 may follow block 720, which is then followed by block 714, 718, 722, and 724. In other aspects, some blocks may be omitted from process 700. For instance, in some aspects, block 714 may not be included in process 700. In some aspects, additional processes can be defined in memory of a master controller and/or local controller of a cooling system. In some aspects, blocks 714, 716, 718, 720, 722, and 724 are operated continuously during the operation of the RPU, and are performed simultaneously (e.g., the blocks and their corresponding processes are not performed in sequence with respect to each other). The process 700 can be continuously evaluate (e.g., can operate as a loop) and can continuously monitor a state of the master controller at block 702 and of the pumps (e.g., the local controllers corresponding to the pumps) at block 704.

In some aspects, pumps of an RPU can operate in a switchover mode, which can alternate pumps between an active state (e.g., an operational state in which the pump is pumping fluid through the cooling system) and a passive state (e.g., with the pump turned off). In some cases, a switchover between pumps can be performed at regular time intervals, as can advantageously equalize a wear incurred on the respective pumps. A first pump may thus be active in a first time period and can be controlled according to a PID controller implemented by a master controller of the cooling system to achieve a set point for an operational parameter of the cooling system. While the first pump is active, a second pump can be passive or inactive. After a first time interval, the master controller can initiate a switching process to make the first pump a passive pump and make the second pump active. In a preferred embodiment, a third speed signal can be generated to decrease (e.g., ramp down) a speed of the first pump. After a second time interval subsequent to and equal to the first time interval, the master controller can initiate the switching process to make the first pump an active pump and the second pump a passive pump. In other embodiments, a first ramp instruction (e.g., an instruction from the master controller to local controller which instructs the local controller to increase the speed of a pump) can be sent to the first pump to increase a speed of the first pump. In other embodiments, a second ramp instruction (e.g., an instruction from the master controller to local controller which instructs the local controller to increase the speed of a pump) can be sent to the second pump to decrease a speed of the second pump. This procedure can advantageously extend the life of the individual pumps and ensure that a pumps of an RPU do not wear disproportionately to the other pump. In some cases, a switchover can be initiated manually (e.g., a switchover can be initiated in response to an operator command at one of a UI, CLI, API, a button including, for example, the buttons 512a, 512b shown in FIG. 5, upon an unlock operation at one of locking systems 616a, 616b shown in FIG. 6, etc.), or a switchover can be initiated upon a condition (e.g., a failure at any of a VFD 608, pump motor 610, fan 612, locking system 616, or lighting elements 618 shown in FIG. 6).

In this regard, FIG. 8 illustrates a process 800 for implementing a switchover process for pumps of an RPU. In some aspects, the process 800 is an example of a switchover process that can be performed by process 700 at block 718, illustrated in FIG. 7. The process 800 can be continuously evaluated (e.g., in a loop). The switchover process 800 can check if a power button of the active pump has been depressed (e.g., pressed) for a length of time that is greater than or equal to a first time interval (e.g., the power button 512 shown in FIG. 5). In a preferred aspect, the time interval is at least 0.1 s, but in other aspects, a switchover process can require a depression of a power button for longer or shorter periods. If the power button is depressed, a power button signal may be received by electronic devices (e.g., local controller, master controller, etc) that are in electrical communication. If the button is pressed at block 802, the process 800 can proceed to initiate a switchover (e.g., pressing the button can start the process to shut off the currently active pump, and make the currently passive pump active). In some cases, the local controller of the pump cassette including the poser button (e.g., local controller 606a, of pump cassette 604a when button 610a is pressed) can communicate a state of the button, or an indication that the button has been pressed to the master controller (e.g., the master controller 602), and the master controller can provide instructions to both of the local controller of the currently active pump cassette (e.g., local controller 606a) and to the local controller of the currently passive pump cassette (e.g., local controller 606b) to implement the process 700 (e.g., or other ramping processes). The process 700 can include ramping up a speed of the passive pump at a predetermined rate to achieve the speed of the currently active pump. Ramping up a speed a passive pump can include generating, at the master controller, a ramp instruction (e.g., a command to change a speed by a predetermined interval) and communicating the ramp instruction to the local controller, and issuing a command (e.g., a command to change the speed by a predetermined amount). In some aspects, the master controller (e.g., the master controller 602 shown in FIG. 6) communicates a target speed to the local controller (e.g., the local controller 606a shown in FIG. 6), and the controller increments a speed of a pump motor (e.g., pump motor 610a shown in FIG. 6) at a given rate to achieve the target speed. In some aspects, the master controller continuously increments the speed of the previously passive pump to achieve a given flow rate between the previously active pump and the previously passive pump during the switchover operation. The speed of the previously active pump can be decreased (e.g., ramped down) incrementally at block 808 while the speed of the previously passive pump is increased (e.g., ramped up). At block 810 the ramping can proceed for both of the pumps, and the process 800 can continuously evaluate whether the switchover is complete at block 812 by determining if the previously active pump has been shut off (e.g., a speed of the first pump is 0 revolutions per minute (RPM)), and if the previously passive pump is at the set speed. Once the process 800 is complete, it can return to the beginning to evaluate whether switchover is again required. If, at block 802, the power button is not pushed, the process 800 can return to reevaluate a need for switchover.

In some aspects, the process 800 can evaluate whether a given time is elapsed to decide whether to initiate a switchover (e.g., begin the ramp up at block 806 and the ramp down at block 808). In some aspects, a time period can be configured in the master controller for regular switching of the pumps. The time period can be an interval of minutes, hours, days, weeks, etc. In some aspects, an interval for switching between pumps of an RPU is configurable by an operator of the cooling system. If the set time period has elapsed, the process can initiate a switchover, as described above (e.g., additionally or alternatively to evaluation of a state of a button at block 802). If the time period has not elapsed, the process 800 can return to the beginning, and again evaluate if a switchover is necessary. In a preferred aspect, the process 800 is evaluated for a time period at block 804. In some aspects, a process for switching pumps can further include setting a local variable on each of the local controllers (e.g., local controllers 606a, 606b shown in FIG. 6) indicating a current state of the pump. For example, a state variable of the local controller can be set to “1” if the pump is the primary pump, or to “0” if the pump is the passive pump. In other aspects, other values can be used to indicate a state of the pump, such as Boolean values, numerical values, or strings.

In some aspects, it can be advantageous to prevent downtime of the system, by providing systems and processes for maintaining an operation of components of an RPU pump cassette when a communication is lost with a master controller. For example, if both pumps of an RPU stop operation, fluid flow to provide cooling can be stopped, which can negatively impact a cooling of computer systems and electronics cooled by the cooling system. In some cases, emergency control methods implemented at local controller of pump cassettes can reduce a number of electrical connections of an RPU cassette and can advantageously allow for the use of Modbus communication protocols between the master controller and local controllers. For example, in the control system 600 illustrated in FIG. 6, the master controller 602 is connected directly to the local controllers 606a, 606b (e.g., the master controller is not directly in communication with electrical components of the pump cassette, including VFDs 608, pump motors 610, fans 612, locking systems 616, and lighting elements 618). This arrangement can facilitate an autonomous operation of local controllers 606a, 606b to operate the electronic components of a corresponding pump cassette when communication is lost with the master controller 602. Processes can thus be provided to continue operation of the RPU to continue providing cooling even in the event of a failure, include a loss of communication between the master controller (e.g., master controller 190 shown in FIG. 1A, master controller 590 shown in FIG. 5, master controller 602 shown in FIG. 6) and a local controller of a pump cassette (e.g., either or both of local controllers 606a, 606b shown in FIG. 6). FIG. 9, for example, illustrates a process 900 that can be used to operate pumps and electronic components of pump cassette of an RPU when connectivity to the master controller (e.g., master controller 602 shown in FIG. 6) is lost at a local controller (e.g., one of the local controllers 606a, 606b shown in FIG. 6). In some aspects, the process 900 is an example of an emergency operation that can be implemented at block 714 of process 700 shown in FIG. 7.

At block 902, a local controller for a pump cassette (e.g., the local controllers 606a, 606b shown in FIG. 6) can evaluate whether a connection (e.g., a wired or wireless connection) to the master controller has been lost for longer than a preset dead time. In some cases, including as illustrated, the connection can adhere to Modbus communication protocols. The Modbus dead time can be a variable set at the local controller as a system setting or can be received as a setting from the master controller. A dead time (e.g., the Modbus dead time shown in FIG. 9) can be configurable by an operator of the cooling system, and can be set in seconds, minutes, or hours. In some aspects, a default time period for the Modbus dead time setting can be 30 seconds. If a connection is detected with the master controller at block 914, a priority variable (e.g., the control priority described with respect to block 712 of process 700 shown in FIG. 7) in the memory of the local controller can be set to indicate a priority of the master controller, and the process 900 can return to block 902. In some aspects, if a connection is detected with the master controller, the priority variable is set to “1”, indicating that the local controller is a worker receiving instructions from the master controller. In some aspects, the priority variable can be set by instructions from the master controller. For example, at block 916, the master controller can evaluate whether a connection to the local controller has been lost for longer than a preset set dead time (e.g., similar to block 902). In some aspects, if there is connectivity, at block 918, the master controller issues an instruction to the local controller to set the priority variable (e.g., the priority variable in the memory of the local controller) to “1” to indicate that the local controller is a worker and the master controller is the master. In some cases, determining connectivity at either or both of blocks 902 can include monitoring from a communication from the other of the local controller or the master controller. For example, the master controller can be configured to “ping” (e.g., to issue a periodic communication) the local controller at regular intervals (e.g., every 1 ms, 5 ms, 10 ms, 100 ms, 1 s, etc.), and the local controller can determine that connection is lost to the master controller if no pings or other communications are received within the preset dead time. In some cases, communication can be determined from a response received from one or both of the master controller and the local controller. For example, when a master controller pings a local controller, the local controller can send a response, and that response can be received at the master controller to determine that a connection to the master controller has been established. In some cases, a local controller can determine a communication at block 902 by periodically communicating with (e.g., pinging) the master controller and determining a response. In some cases, communication between a master controller and a local controller can be determined using any known protocols for establishing or confirming a connection between system components (e.g., using Modbus protocols, TCP protocols, SNMP protocols, etc.).

If, at block 902, there is no connection between the master controller and the local controller for longer than the preset dead time, the local controller can be switched to operate in an autonomous mode, and can autonomously control the electrical components of the pump cassette (e.g., the VFD 608, locking system 616, lighting elements 618, and fan 612 of pump cassette 604 illustrated in FIG. 6) until connection to the master controller is restored. In this regard, at block 904, the local controller can set the priority variable to indicate that the local controller takes priority, thus providing the local controller autonomy in operation of the electrical components of the pump cassette. In some aspects, the priority variable is set to “0” to indicate that the local controller is operating autonomously. In other aspect, other values can be used for the priority variable, including, for example, Boolean values, numerical values, or strings. In some aspects, the local controller assumes control of all electrical components of the pump cassette when the priority variable is set at block 904 to set an operating mode of the local controller to autonomous operation. In other examples, a control priority can be indicated by variables of other values or types. For example, a variable for a control priority can be set to “TRUE” if the master controller is operating to instruct the local controller and “FALSE” if the local controller is operating in autonomous mode. In some cases, a control priority can be indicated by any value readable by a process of the local controller.

At block 906, the process can check if the pump for the given pump cassette (e.g., pump cassette 502 shown in FIG. 5, pump cassette 606 shown in FIG. 6, or any pump cassette of an RPU) was active at the time communication was lost with the master controller. In some aspects, a memory of the local controller can include a variable indicating whether the pump is designated as active or passive (e.g., as described above with respect to FIG. 8). In some aspects, a memory of the local controller can include the last target speed received from the master controller, and if the target speed was greater than zero, the process 900 can determine that the pump was active. If the pump was not designated as an active pump, the pump can remain off (e.g., the local controller can maintain a passive state of the pump) and the process can return to block 902 to evaluate the connectivity of the local controller to the master controller. In some cases, including when connection with the master controller is lost during the operation of a switchover procedure (e.g., the process 800 shown in FIG. 8), a local controller can continue a ramp-down operation of a pump when operating in autonomous mode, with a target speed of the pump being ramped down as 0 rpm (e.g., when the pump is a pump designated as a passive pump, and is in the middle of a ramp down operation when connection with the master controller is lost).

If, at block 906, the process 900 determines that the pump was active, the pump can be ramped to a preset speed at block 908. The preset speed can be a speed value stored in a memory of the local controller. In some aspects, the preset speed can be the last target speed received from the master controller. In some aspects, the preset speed can be a default speed that is independent of a speed received from the master controller. A preset speed for a pump (e.g., a speed at which to operate the pump when the local controller is in autonomous mode) can be set by an operator of cooling system (e.g., ICD 120 shown in FIG. 1A) in which the RPU is installed). In some cases, the preset speed can be a speed stored in the master controller, and can be set on the local controller through a command received from the master controller when the master controller is in communication with the local controller.

At block 910, the process 900 can check if the power button (e.g., the power button 614 shown in FIG. 6) is pressed for a preset time interval. In some aspects, the process 900 can check if the power button has been pressed for longer than 0.1 s. If the power button has been pressed for longer than 0.1 s, as shown, the process 900 can proceed to shut down the pump at block 912. Shutting down the pump can include ramping down a speed of the pump at a given rate or by given intervals until the speed of the pump is zero. In some aspects, if the power button is pressed again, the pump can be turned on, and ramped up to the preset speed. If the pump was the passive pump at the time the control priority was changed to autonomous mode at block 904, pressing the power button can have no effect on the operation of the pump, and the pump can remain in passive state with the pump speed set to zero. The process 900 can return to block 902 to evaluate connection of the local controller to the master controller, and can continuously monitor for connection to the master controller. When connection is reestablished with the master controller at block 902, the local controller can receive an instruction from the master controller to set the control priority at block 914, and the control priority can be set to provide the master controller control over operation of the local controller and electronic components of the pump cassette.

As partially described above, a master controller can perform an emergency control routine to implement part of process 900 when connection to one or more local controllers of pump cassette is lost. For example, as shown, if, at block 916 (e.g., similar to block 902), the master controller can determine that connection to the local controller has been lost for longer than a preset dead time. If connection has been lost for longer than the preset dead time, at block 920, the master controller can generate an alarm and log an error indicating the lost connectivity to an operator, or to monitoring or maintenance systems for the cooling system. In some aspects, the error that is logged may be “E101,” or any other combination of alpha numerical values. In some aspects, the alarm generated and logged at block 920 can be an alert that can be provided to an operator of the RPU (e.g., through any of the alerting methods described with respect to blocks 706, 708, 710 shown in FIG. 7). In some cases, a communication between a local controller and a master controller can be interrupted due to a removal of the master controller from the RPU (e.g., a removal of replaceable controller 590 from RPU 500 shown in FIG. 5). When a master controller is removed or otherwise fails, the process 900 can be implemented on only the local controller (e.g., the master controller does not operate to implement blocks 916, 918, and 920).

While process 900 is described with respect to the pumps of a pump cassette, other electrical elements can be operated by a local controller in an autonomous mode when communication is lost with a master controller. For example, if a connection with a master controller is lost for greater than a preset dead time (e.g., as determined at block 902), a local controller (e.g., local controller 606a shown in FIG. 6) can operate a PID controller to control a fan speed of a fan of the pump cassette (e.g., fans 612a, 612b). In an autonomous mode, the local controller can control an operation of LEDS (e.g., lighting elements 618a, 618b shown in FIG. 6, LEDS 508a, 508b, 510a, 510b shown in FIG. 5, etc.). In some cases, the local controller can operate the LEDs to provide an indication to an operator that the pump cassette has lost a communication with a master controller (e.g., through a blinking pattern of the LEDs, illumination of a combination of LEDs, or of a LED of a particular color). In an example, when communication is lost with the master controller, a local controller for a pump cassette can cause a red LED (e.g., LED 508a shown in FIG. 8) to blink at a rate of 4 Hz. In some aspects, a local controller can implement emergency control procedures for any electronic component of a pump cassette when communication between the local controller and the master controller is interrupted.

In some aspects, lighting elements of the respective pump cassette (e.g., LEDs 508, 510 of pump cassettes 502 shown in FIG. 5) can communicate a state of the local controller (e.g., local controller 606) to an operator, including a loss of connectivity to the master controller (e.g., the master controller 602). In some aspects, including while the local controller is operating in emergency mode, as shown in FIG. 9, the local controller can control operation of the lighting elements. For example, when communication to the local controller is lost at block 902, and the local controller is set to the master at block 904, the local controller can control a LED of the pump cassette (e.g., LED 508 shown in FIG. 5) to communicate to an operator that connectivity has been lost. In some aspects, the LED indicating lost connectivity can be a red LED, and lost connectivity can be communicated by controlling to red LED to blink at a fast rate (e.g., at a rate of about 4 Hz). In some aspects, if the local controller has lost connectivity to the master controller, and the local controller is unable to start the pump motor (e.g., due to a mechanical failure, over-torque, over-heating, etc.), the local controller can control the red LED to be solid red, indicating the failure. In some aspects, the local controller can operate the lighting elements of the pump cassette in accordance with the LED control process shown in FIG. 13.

In some aspects, a process is included for enabling and disabling the operation of a pump. It may be advantageous to disable the operation of a pump for maintenance, inspection, changing pumps, or other instances where the operation of a pump is disabled. Disabling a pump can be a prerequisite to unlocking the pump and removing the pump, as can advantageously reduce a leakage of fluid from the pump cassette during removal from the RPU. Further, it may also be advantageous to ensure that a pump is enabled and ready for operation before the pump is operated to provide pressure along a coolant loop of a cooling system. This process of checking a pump during an enable/disable request is described in a process 1000, depicted in FIG. 10, which is an example of a process that can be implemented at block 716 of process 700 shown in FIG. 7.

At block 1002, the process 1000 determines a requested state for a given pump cassette (e.g., any of pump cassettes 502a, 502b, 604a, 604b). In some cases, a state “request” can be triggered by a system event. For example, an “Enable” request can be triggered when a local controller is powered on, or a communication with the master controller is established. In some examples, when a pump cassette is inserted in an RPU and a limit switch of a locking system (e.g., any of locking systems 616a, 616b) is engaged, this engagement can initiate a request to enable to the pump cassette (e.g., the insertion of a pump cassette into the RPU can initiate an operation to start a pump of the RPU cassette). In some cases, a state can be manually requested by an operator through an interface (e.g., a button, a UI, an API, a CLI, etc.). In some cases, a request to change a state can be made in response to a system parameter. For example, if a heat of a pump rises above a threshold temperature, this condition can trigger a request to change a state of the pump cassette to “disabled”. In some cases, a state request can be triggered according to operator-defined triggers. In some cases, a state request can be initiated from a master controller (e.g., master controller 190 shown in FIG. 1A, replaceable controller 590 shown in FIG. 5, or master controller 602 shown in FIG. 6) via an instruction issued from the master controller to the local controller.

If, at block 1002 the requested state is “disabled,” the process can proceed to block 1004, and a master controller (e.g., any of master controller 190 shown in FIG. 1A, removable controller 590 shown in FIG. 5, master controller 602 shown in FIG. 6) can read a “status word” of the pump cassette to determine a current status of the pump cassette and electrical components thereof (e.g., local controller 606a, VFD 608a, pump motor 610a, fan 612a, and lighting elements 618a of pump cassette 604a). In some cases, the request can be performed over a Modbus communication in which the master controller requests the value of a variable from the local controller. For example, a table stored in a memory of the local controller (e.g., either of local controllers 606a, 606b) can include an input register, and the input register can include a “status word” variable at a predetermined address of the input register (e.g., in accordance with a Modbus protocol). The status word variable can be an integer value (e.g., an integer represented by a 16-bit binary value) and integer values can correspond to particular statuses of the pump cassette. For example, an integer value of “0” can indicate that the pump of the pump cassette is not ready to be switched on (e.g., as part of a switching operation similar or identical to process 800 shown in FIG. 8). In some examples, the status word can have an integer value for any or each of the following possible statuses: “switch on disabled,” “ready to switch on,” “switched on,” “operation enabled,” “quick stop active,” fault reaction active,” or “fault.” In the illustrated aspect, reading the status word can include the master controller issuing a request to the local controller, indicating the address of the status word to be read, and the local controller responding to the master controller with a payload including the integer value of the status word (e.g., the 16-digit binary value, which can be referred to as a “word”). In other examples, including where the process 1000 is performed using a protocol other than Modbus, a local controller can advertise a status word to the master controller (e.g., the process 1000 checks the state of the request through a “push” method, wherein a local controller periodically sends a communication to the master controller indicating a value of the status word). In some aspects, a status word can be an alphanumeric value, a float value, or any other variable type capable of indicating a status of the respective pump cassette (e.g., a status of a pump, local controller or other electronic components of a pump cassette). In some cases, a status word can be specific to certain components of the pump cassette (e.g., a status word can indicate a status of a local controller 606, the VFD 608, the pump motor 610, the fan 612, the locking system 616, the lighting elements 618, etc.). In some example, status words can include more or fewer status words indicating a greater or lesser number of potential statuses of a pump cassette.

In some cases, including, for example, when the pump cassette is initially inserted into the RPU (e.g., when the pump cassette 502a is inserted into RPU 500), a status word of the pump cassette can be a value indicating a “ready to switch” status. A status of “ready to switch,” (e.g., as indicated by an integer value of the status word variable stored at an address of the input register) can indicate that one or more conditions have been met to allow the pump of a pump cassette (e.g., pump 504a of pump cassette 502a shown in FIG. 5, or pump motor 610a of pump cassette 604a shown in FIG. 6) to begin operation. For example, a status of “ready to switch” at block 1004 can indicate that there are no active faults that would prevent the safe switchover of the pump of the pump cassette.

If, at block 1004, the status word indicates a status of “enabled,” the process 1000 can proceed to block 1006, and the master controller can issue a command to the local controller to disable a pump of the local controller (e.g., the master controller 602 can issue a command to local controller 604a to end an operation of pump motor 610a). In some cases, issue a command from a master controller to a local controller to enable a pump can include writing, by the master controller, a variable of the local controller via established Modbus protocols. For example, a “control word” variable can be stored in a writable table (e.g., the control word variable illustrated in Table 3) in a memory of the local controller, at a predetermined address. In some aspects, the control word “HR156” may be given a value of “6,” “7,” “15,” “0,” “2,” “7,” or any other value. Once a command is issued at block 1006, the process 1000 reads the status word at block 1004.

If, at block 1004, the status word variable of the local controller indicates a status of “switch on,” the master controller can issue a command to the local controller of the pump cassette to unlock a solenoid at a block 1012 (e.g., a solenoid of the locking system 616a of pump cassette 604a). The solenoid may be locked to prevent the removal of a pump cassette from an RPU. Unlocking the solenoid may allow a pump cassette to be removed relative to an RPU. Further, the unlocking of the solenoid may allow flow connection modules of a pump cassette (e.g., connections 232, 234 of flow connection module 230 illustrated in FIG. 1B) to be decoupled from corresponding flow connection modules of an RPU (e.g., flow connection 152, 154 of flow connection module 150, illustrated in FIG. 1B). The decoupling of the flow connection modules and unlocking of the solenoid may allow for a switchover process to occur (e.g., a process similar or identical to process 800 of FIG. 8). Issuing a command to unlock the solenoid can include providing an instruction from the master controller to overwrite a variable of the local controller. For example, a local controller can have a solenoid variable (e.g., at a writable table in a memory of the local controller, which can include a writable “Coils” table, and a writable “Holding Registers” table in some examples) associated with a desired state of a solenoid, and, upon receiving a command from the master controller, the solenoid variable can be set to “0” (e.g., any of a Boolean, alphanumerical, binary, or integer value representing an “on” state) to indicate that the solenoid should be unlocked. In other aspects, a variable corresponding to a desired state of a solenoid can include any variable type. After the solenoid is unlocked at block 1012, in some aspects, the process 1000 reads the status word at block 1004 once more.

If the status word at 1004 is anything besides “enabled,” “ready to switch,” or “switched on,” process 1000 proceeds to block 1008 and logs an alarm. In some aspects, the error that is logged may be “E106,” or any other combination of alpha numerical values. In some aspects, the alarm generated and logged at block 1008 can be an alert that can be provided to an operator of the RPU (e.g., through any of the alerting methods described with respect to blocks 706, 708, 710 shown in FIG. 7). In some aspects, the master controller can generate an alarm and log an error indicating that the status word is not one of the above referenced status words, indicating that the system is not in an expected state. For example, if a pump cassette related to an RPU does not have an expected status word value (e.g., “enabled,” “ready to switch,” or “switched on”), then an alarm may be written to indicate that the pump cassette is not ready for a mode of operation (e.g., a process similar or identical to 800, process 1100, etc.).

If, at block 1002 the requested state is “enabled,” the process can proceed to block 1014, and a master controller (e.g., any of master controller 190 shown in FIG. 1A, removable controller 590 shown in FIG. 5, master controller 602 shown in FIG. 6) can read a “status word” of the pump cassette to determine a current status of the pump cassette and electrical components thereof (e.g., local controller 606a, VFD 608a, pump motor 610a, fan 612a, and lighting elements 618a of pump cassette 604a). In some aspects, block 1014 is substantially similar to block 1004 and may be requested in substantially identical methods as block 1004. For example, an integer value of “0” can indicate that the pump of the pump cassette is not ready to be switched on (e.g., as part of a switching operation similar or identical to process 800 shown in FIG. 8). In some examples, the status word can have an integer value for any or each of the following possible statuses: “switch on disabled,” “ready to switch on,” “switched on,” “operation enabled,” “quick stop active,” fault reaction active,” or “fault.” In the illustrated aspect, reading the status word can include the master controller issuing a request to the local controller, indicating the address of the status word to be read, and the local controller responding to the master controller with a payload including the integer value of the status word (e.g., the 16-digit binary value, which can be referred to as a “word”). In other examples, including where the process 1000 is performed using a protocol other than Modbus, a local controller can advertise a status word to the master controller (e.g., the process 1000 checks the state of the request through a “push” method, wherein a local controller periodically sends a communication to the master controller indicating a value of the status word). In some aspects, a status word can be an alphanumeric value, a float value, or any other variable type capable of indicating a status of the respective pump cassette (e.g., a status of a pump, local controller or other electronic components of a pump cassette). In some cases, a status word can be specific to certain components of the pump cassette (e.g., a status word can indicate a status of a local controller 606, the VFD 608, the pump motor 610, the fan 612, the locking system 616, the lighting elements 618, etc.). In some example, status words can include more or fewer status words indicating a greater or lesser number of potential statuses of a pump cassette.

In some cases, including, for example, when the pump cassette is initially inserted into the RPU (e.g., when the pump cassette 502a is inserted into RPU 500), a status word of the pump cassette can be a value indicating a “ready to switch” status. A status of “ready to switch,” (e.g., as indicated by an integer value of the status word variable stored at an address of the input register) can indicate that one or more conditions have been met to allow the pump of a pump cassette (e.g., pump 504a of pump cassette 502a shown in FIG. 5, or pump motor 610a of pump cassette 604a shown in FIG. 6) to begin operation. For example, a status of “ready to switch” can indicate that there are no active faults that would prevent the safe operation of the pump of the pump cassette.

If, at block 1014, the status word variable of the local controller indicates a status of “ready to switch on,” the master controller can issue a command to the local controller of the pump cassette to lock a solenoid (e.g., a solenoid of the locking system 616a of pump cassette 604a). Locking the solenoid can engage a locking system for a pump cassette to prevent removal of the pump cassette from an RPU. Locking a pump cassette relative to an RPU (e.g., preventing a displacement of the pump cassette relative to the RPU) can prevent a removal of the pump cassette, and a decoupling of flow connection modules of the pump cassette (e.g., connections 232, 234 of flow connection module 230 illustrated in FIG. 1B) from corresponding flow connection modules of an RPU (e.g., flow connection 152, 154 of flow connection module 150, illustrated in FIG. 1B), and can thereby prevent a leakage along a cooling system upon removal of a pump cassette from an RPU. Issuing a command to lock the solenoid can include providing an instruction from the master controller to overwrite a variable of the local controller. For example, a local controller can have a solenoid variable (e.g., at a writable table in a memory of the local controller, which can include a writable “Coils” table, and a writable “Holding Registers” table in some examples) associated with a desired state of a solenoid, and, upon receiving a command from the master controller, the solenoid variable can be set to “1” (e.g., any of a Boolean, alphanumerical, binary, or integer value representing an “on” state) to indicate that the solenoid should be locked. In other aspects, a variable corresponding to a desired state of a solenoid can include any variable type.

A local controller can issue a signal to a solenoid, responsive to a solenoid variable indicating a desired “locked” state, to lock the solenoid (e.g., to provide a current to engage the solenoid). In some cases, a state variable for the solenoid can indicate an actual state of the solenoid (e.g., a position of the solenoid). For example, a limit switch can be provided for a locking system (e.g., locking system 616a shown in FIG. 6), and the position of the limit switch can correspond to an input state variable stored at a memory of a local controller (e.g., local controller 606a, shown in FIG. 6). In an example, the limit switch can be in a first position, corresponding to an “unlocked” position of the solenoid, or in a second position corresponding to a “locked” position of the solenoid. A variable corresponding to the position of the limit switch can thus indicate an actual position of the solenoid (e.g., and therefore a “locked” or “unlocked” state of the solenoid). In an example, a value of “1” for an input state variable can indicate that the limit switch is in the second position (e.g., the solenoid is “locked”) and a value of “0” for the input state variable can indicate that the limit switch is in the first position (e.g., the solenoid is “unlocked”). In some cases a bit at a predetermined location of a variable can correspond to a state of a solenoid. For example, the solenoid state can be stored at bit 0 of the digital input status variable illustrated in Table 2, with a value of “1” at bit 0 of the variable indicating a locked state of the solenoid, and a value of “0” at bit 0 being an unlocked state of the solenoid. At block 1020, the master controller can read the input state variable to determine an actual state of the solenoid. In some cases, reading the input state variable can include the same procedure as reading the status word at block 1014, with the master controller providing an address of the input state variable to be read to the local controller, and the local controller responding with the value of the input state variable.

If, at block 1022, the input state variable 1022 indicates that the solenoid is unlocked, the process 1000 can proceed to block 1024 and log an alarm. The alarm can indicate an unlocked state of the solenoid and can include a code corresponding to a particular error. In some cases, the alarm can include a plaintext message, indicating that the solenoid is unlocked. In some cases, logging an alarm at block 1024 can be substantially similar to logging alarms at any of blocks 706, 708, 710 shown in FIG. 7. The process 1000 can conclude at block 1024 (e.g., upon determining that a solenoid is unlocked) and the pump of the pump cassette (e.g., the pump 504a of the pump cassette 502a) can remain off while the solenoid is unlocked.

If, at block 1022, the input state variable indicates that the solenoid is locked, the process 1000 can proceed to block 1018, and the master controller can issue a command to the local controller to enable a pump of the local controller (e.g., the master controller 602 can issue a command to local controller 604a to initiate an operation of pump motor 610a). In some cases, issue a command from a master controller to a local controller to enable a pump can include writing, by the master controller, a variable of the local controller via established Modbus protocols. For example, a “control word” variable can be stored in a writable table (e.g., the control word variable illustrated in Table 3) in a memory of the local controller, at a predetermined address. In some aspects, if the status word of block 1014 is “switched on,” the process may write a control word at block 1018, which may enable the pump of the local controller.

If, in some aspects, at block 1014, the status word read is not “ready to switch on” or “switched on,” an alarm may be logged at block 1016. The error code logged at block 1016 may be any alpha numerical value designated to indicate an absence of a pump (e.g., an alarm id “E109,” a message indicated the enabled state is not in operation correctly, a standardized log entry or SNMP alert indicating the enabled state is not in operation correctly, etc.). In some cases, logging an alarm can include writing an error message to a log entry of the system. In some cases, logging an alarm can include issuing a notification (e.g., a remote notification at a web interface, a text message, an alert in an application, an email communication, etc.) to an operator of a status of the respective pumps of the RPU.

In some aspects, fan control is desired. To control a fan, a process may be used to check the operational state of a fan and report to a controller. In some aspects, the controller may be a local controller (e.g., a slave controller). The local controller may record the state of the fan and push the state to a master controller. In other aspects, the local controller may provide the state to a master controller in response to a request from the master controller (e.g., the state is “pulled” from the local controller). In some aspects, a fan may be desired to be turned off because the internal temperature of the system is cool enough. In another aspect, the fan may need to be turned off for maintenance or inspection. In yet another aspect, the fan may need to be turned off because a different part of the system is not in operation. A process 1100 of FIG. 11 described how a fan may be controlled. In some aspects, the process 1100 may be used in a continuous loop.

The process 1100 determines whether or not the fan is desired to be off at a block 1102. In some aspects, the master controller determines whether the fan is desired to be turned off. The master controller may determine the state of the fan through a temperature reading of the system, which may indicate that the temperature is low enough that the operation of a fan is not necessary. In other aspects, the master controller may receive an input from another process (e.g., a process similar or identical to process 800, process 1000, an external input, etc.) which requests that the fan operation is turned off. In some aspects, the fan operation is turned off due to routine maintenance.

If the fan is desired to be turned off, a fan state is read at block 1104. If the fan state is “off,” or not in operation, an alarm is logged in block 1106. In an example, a value of “1” for the fan state can indicate that the fan is on (e.g., the fan is in operation) and a value of “0” for the input fan state can indicate that the fan is off (e.g., the fan is not in operation). In some aspects, the alarm is logged to indicate that the fan is not in operation according to the fan state, while the block 1102 indicates that the fan is in operation. In a preferred aspect, the alarm code is “E103,” but may be any other alpha numerical value in other aspects.

If the fan state is “on,” then an output state is written at block 1108. In FIG. 11, block 1108 writes a command to turn off the fan. Issuing a command to turn off the fan can include providing an instruction from the master controller to overwrite a variable of the local controller. For example, a local controller can have a fan variable (e.g., at a writable table in a memory of the local controller, which can include a writable “Coils” table, and a writable “Holding Registers” table in some examples) associated with a desired state of a fan, and, upon receiving a command from the master controller, the fan variable can be set to “0” (e.g., any of a Boolean, alphanumerical, binary, or integer value representing an “on” state) to indicate that the fan should be turned off. In other aspects, a variable corresponding to a desired state of a fan can include any variable type.

The fan state is then read at block 1110. If block 1110 reads the state of the fan to be “on,” an alarm is logged at block 1112. If the fan state is “on,” or in operation, an alarm is logged in block 1112. In an example, a value of “1” for the fan state can indicate that the fan is on (e.g., the fan is in operation) and a value of “0” for the input fan state can indicate that the fan is off (e.g., the fan is not in operation). In a preferred aspect, an alarm is written at block 1112 as the fan did not cease operation as commanded in block 1108. In a preferred aspect, the alarm code is “E103,” but may be any other alpha numerical value in other aspects. If the fan is off at block 1110, then the process 1100 is ended. In some instances, process 1100 begins again as it is in a continuous loop.

Within an RPU system, it may be necessary to include a process that reviews drive errors. Drive errors may be read to determine the status of the error. In some aspects, the drive error my be linked to an alarm text (e.g., an error code). The process 1200 of FIG. 12 depicts a method in which drive errors can be read. The process 1200 may be substantially similar to block 720 of FIG. 7.

In process 1200, a drive errors log is read at block 1202. In a preferred aspect, the drive errors log is related to a variable frequency drive (VFD) (e.g., VFD 608). In some aspects, the drive errors log may be stored in a local controller, or in a master controller. In the aspects that have the drive errors log stored on the local controller, the master controller may pushed the drive errors log. In other aspects, the drive errors log is pulled from the local controller to the master controller. In some aspects, the drive errors log contains a text description of the errors within the drive errors log. For example, in some aspects, the drive errors log may indicate that the temperature of the VFD is too high. In other aspects, the drive errors log may indicate that the overcurrent of the VFD is too high, or too low. In a preferred aspect, the drive errors log indicates that there are errors within the operation of the VFD. If no drive errors are present within the drive errors log, operation is continued as normal in block 1216.

If errors exist within the drive errors log, a log alarm is written. In process 1200, if there are drive errors present, at block 1204, the master controller can generate an alarm and log an error indicating the that there are drive errors present in the drive errors log. In some aspects, the error code that is logged at block 1204 may be “E102,” or any other combination of alpha numerical values. In some aspects, the alarm generated and logged at block 1204 can be an alert that can be provided to an operator of the RPU (e.g., through any of the alerting methods described with respect to blocks 706, 708, 710 shown in FIG. 7).

Once an alarm log is written, indicating the presence of errors in the drive errors log, the drive alarm is then reset. In process 1200, at block 1206, the drive alarm is reset. In some aspects, the drive alarm is reset by providing a solution for the drive alarm. For example, in some aspects, if a temperature of the VFD is too high, a fan may turn on or speed up. In other aspects, the drive alarm is reset by addressing the drive alarms

If a drive fault is not active, then the operation continues as normal. In process 1200, if there are no active drive faults in block 1208, then operation continues as normal in block 1216. In some aspects, the drive fault is not active because the drive alarms have been reset. If a drive fault is still active at block 1208, then block 1210 evaluates if a stop is required. For example, in some aspects, a stop is required if the drive fault is determined to be inoperable.

If a stop is required, then the current system is inoperable, and a switchover may be required. In process 1200, at block 1212, the current system is deemed inoperable, and a switchover process may commence. In some aspects, a system is considered inoperable due to reading from the system. For example, in some aspects, a pressure drop, temperature, flow rate, or any other measurable data may warrant the system inoperable if it exceeds beyond a pre-determined limit. In other aspects, if there is a miscommunication between the system commands and the outputs of the system, the system may be considered inoperable. For example, if a fan is requested to turn off (e.g., similar or identical to process 1100), and still remains on, the system may be considered inoperable. For example, in some aspects, if a pump cassette in an RPU is inoperable due to a temperature reading exceeding a predetermined limit, then a switchover process (e.g., a process similar or identical to process 800) may begin.

If a stop in operation is not required, yet still in a fault, then the system may continue in faulted operation. In process 1200, at block 1214, the current system is deemed faulted, yet operable, and operation may continue. For instance, if a pump cassette is not has a system indicator that is above a pre-determined limit, yet not considered inoperable, the system may continue operation. In some aspects, a fan state being in an incorrect state may indicate a faulted system, but not warrant a switchover process. In some aspects, a system can continue a faulted operation for a pre-determined period. If the drive fault does not require a stop, then the faulted operation may continue.

In some aspects, it is advantageous to include a process for LED control. A LED control process may be used to communicate output states, which can indicate an operating state and a fault state of components of pump cassettes (e.g., cassette 502a, 502b shown in FIG. 5) to an operator. The processes 1300 and 1400 of FIGS. 13 and 14 respectively illustrate a processes for controlling LEDs (e.g., LEDs 508a, 508b, 510a, 510b shown in FIG. 5, lighting elements 618a, 618b shown in FIG. 6) of a pump cassette. In some cases, the process described below can be applicable to control of visual elements of a user interface, which can display virtual LEDs, text, or other visual indicators to communicate a state of the RPU cassette to an operator. The processes 1300 and 1400 may be examples of the LED control at block 724 illustrated in FIG. 7. In some cases, lighting elements of a pump cassette can include a red LED and a green LED (e.g., LED 508a can be a red LED and LED 510a can be a green LED) which can communicate an operational state and a fault state respectively to an operator. In some aspects, a pump cassette can include additional LEDs, having various different colors, with each LED corresponding to a particular parameter or state to be communicated to an operator. In some cases, a pump cassette can include multiple LEDs having the same color, and a function of the LED can be determined by a location of the LED (e.g., a topmost LED can indicate an operational state, and a bottom-most LED can indicate a fault state), or a caption of the LED (e.g., a text label can be provided for the LED describing the LED's function).

FIG. 13 illustrates an example process for controlling operation of a green LED, according to some aspects. The process 1300 can be performed by a master controller (e.g., master controller 190 shown in FIG. 1, removable controller 590 shown in FIG. 5, master controller 602 shown in FIG. 6, etc.), through the master controller writing a value to a variable of a local controller (e.g., local controllers 606a, 606b) to control an operation of a green LED of the corresponding pump cassette (e.g., green LED 508a of pump cassette 502a). In some cases, when communication with the master controller and the local controller is interrupted, the local controller can operate to implement process 1300 and can control operation of the green LED autonomously. At block 1302, a status word (e.g., the status word described with respect to block 1012 of FIG. 10, and illustrated in Table 2) can be read. The operation of the green LED can be dependent on the status word (e.g., the green LED can communicate a status indicated in the status word variable to an operator of the pump cassette). As shown, if the status word indicates a status of “Ready to switch” (e.g., the pump is not the active pump), the master controller can issue an instruction to cause a slow blink (e.g., a blink at a rate of 1 Hz) of the green LED. In some cases, the master controller, or the local controller in autonomous mode, can control an operation of the green LED by writing a value to a variable indicating a desired operation of the green LED. For example, as illustrated in Table 3, a Holding Registers table in a memory of a local controller can include a “Green LED state” variable, and a value of the Green LED state corresponding to a slow blinking can be “1”. At block 1308, then, the master controller can issue an instruction to write the value of the Green LED state to “1” to produce a slow blink for the green LED. If, at block 1302, the status word has a value corresponding to an “Enabled” stated, the process 1300 can proceed to check if the pump (e.g., the pump 504a of cassette 502a shown in FIG. 5, or the pump motor 610a of pump cassette 604a shown in FIG. 6) is ramping at block 1308 (e.g., the local controller is ramping the pump as described with respect to block 806 and 810, illustrated in FIG. 8). If the pump is ramping at block 1308, the green LED can be controlled to perform a fast blink at block 1310 (e.g., a blinking at a rate of 4 Hz, or between 1 Hz and 4 Hz, or greater than 4 Hz). Controlling a green LED to perform a fast blink can include setting a value of a green LED state variable in a Holding Registers table to “2”, as shown in Table 3. If at block 1308, the pump is not ramping (e.g., the pump is operating at the desired speed), the green LED can be controlled at block 1312 to produce a steady on signal (e.g., without blinking). Controlling the green LED to produce a steady signal can include writing a corresponding value to the Holding registers table in a memory of the local controller (e.g., writing the Green LED state to “3” as shown in Table 3). If the status word actual does not read “ready to switch,” “enabled,” or “switched,” the output state is written at block 1304, and the green LED can be off (e.g., the green LED state can be written to a value of “0” as shown in Table 3). In other aspects, a state of a green LED can be controlled by writing other values to a corresponding variable, or a green LED state can be controlled directly from reference to another variable (e.g., the status word variable shown in FIG. 2).

FIG. 14 illustrates an example process for controlling operation of a red LED, according to some aspects. The process 1400 can be performed by a master controller (e.g., master controller 190 shown in FIG. 1, removable controller 590 shown in FIG. 5, master controller 602 shown in FIG. 6, etc.), through the master controller writing a value to a variable of a local controller (e.g., local controllers 606a, 606b) to control an operation of a red LED of the corresponding pump cassette (e.g., green LED 508a of pump cassette 502a). In some cases, when communication with the master controller and the local controller is interrupted, the local controller can operate to implement process 1400 and can control operation of the red LED autonomously. At block 1402, active alarms are checked for (e.g. any alarms present in the RPU, and/or log alarms in process 700, process 900, process 1000, process 1100, and/or process 1200). The operation of the red LED can be dependent on the active alarms (e.g., the red LED can communicate a status indicated in the active alarm variable to an operator of the pump cassette). As shown, no active alarms indicates that there are not alarms present (e.g., there are no alarms in the drive error log), the master controller can issue an instruction to cause the red LED to remain off. In some cases, the master controller, or the local controller in autonomous mode, can control an operation of the red LED by writing a value to a variable indicating a desired operation of the red LED. For example, as illustrated in Table 3, a Holding Registers table in a memory of a local controller can include a “Red LED state” variable, and a value of the Red LED state corresponding to off can be “0”. At block 1404, then, the master controller can issue an instruction to write the value of the Red LED state to “0” to have the red LED be off.

If, at block 1402, there are active alarms, the process 1400 can proceed to check the priority of the alarm (e.g., a similar process to evaluating if a stop is needed at block 1210). If the alarm priority is “low,” the red LED can be controlled to perform a slow blink (e.g., a blink at a rate of 1 Hz). In some cases, the master controller, or the local controller in autonomous mode, can control an operation of the red LED by writing a value to a variable indicating a desired operation of the red LED. For example, as illustrated in Table 3, a Holding Registers table in a memory of a local controller can include a “Red LED state” variable, and a value of the Red LED state corresponding to a slow blinking can be “1”. At block 1408, then, the master controller can issue an instruction to write the value of the Red LED state to “1” to produce a slow blink for the red LED.

If, at block 1406, the priority of the active alarm is “medium,” the red LED can be controlled to perform a fast blink (e.g., a blinking at a rate of 4 Hz, or between 1 Hz and 4 Hz, or greater than 4 Hz). Controlling a red LED to perform a fast blink can include setting a value of a red LED state variable in a Holding Registers table to “2”, as shown in Table 3. In other aspects, a state of a red LED can be controlled by writing other values to a corresponding variable, or a red LED state can be controlled directly from reference to another variable (e.g., the status word variable shown in FIG. 2). At block 1410, then, the master controller can issue an instruction to write the value of the Red LED state to “2” to produce a fast blink for the red LED.

If, at block 1406, the alarm priority is high, the red LED can be controlled at block 1412 to produce a steady on signal (e.g., without blinking). Controlling the red LED to produce a steady signal can include writing a corresponding value to the Holding registers table in a memory of the local controller (e.g., writing the Red LED state to “3” as shown in Table 3). In other aspects, a state of a red LED can be controlled by writing other values to a corresponding variable, or a red LED state can be controlled directly from reference to another variable (e.g., the status word variable shown in FIG. 2). At block 1412, then, the master controller can issue an instruction to write the value of the Red LED state to “3” to produce a steady on signal for the red LED.

An alarm may be logged in different ways. For instance, an alarm may be logged by an LED indicator. For example, if a LED is logged by implementing a red LED, a process similar to process 1400 may be used to evaluate the priority of the alarm. In another aspect, an alarm may sent to a database to be logged. The database may be located on the master controller, or the slave. If the database is located on the slave, the master controller may have the alarm log pushed by the slave controller, or the alarm log may be pulled by the master controller. In another aspect, the alarm may be logged via a display indicating that there is an alarm. An alarm may be logged via one, multiple, or a combination of the methods listed herein.

In some aspects, aspects of the disclosure, including computerized implementations of methods according to the disclosure, can be implemented as a system, method, apparatus, or article of manufacture using standard programming or engineering techniques to produce software, firmware, hardware, or any combination thereof to control a processor device (e.g., a serial or parallel general purpose or specialized processor chip, a single- or multi-core chip, a microprocessor, a field programmable gate array, any variety of combinations of a control unit, arithmetic logic unit, and processor register, and so on), a computer (e.g., a processor device operatively coupled to a memory), or another electronically operated controller to implement aspects detailed herein. Accordingly, for example, aspects of the disclosure can be implemented as a set of instructions, tangibly embodied on a non-transitory computer-readable media, such that a processor device can implement the instructions based upon reading the instructions from the computer-readable media. Some aspects of the disclosure can include (or utilize) a control device such as an automation device, a special purpose or general purpose computer including various computer hardware, software, firmware, and so on, consistent with the discussion below. As specific examples, a control device can include a processor, a microcontroller, a field-programmable gate array, a programmable logic controller, logic gates etc., and other typical components that are known in the art for implementation of appropriate functionality (e.g., memory, communication systems, power sources, user interfaces and other inputs, etc.). In some aspects, a control device can include a centralized hub controller that receives, processes and (re)transmits control signals and other data to and from other distributed control devices (e.g., an engine controller, an implement controller, a drive controller, etc.), including as part of a hub-and-spoke architecture or otherwise.

The term “article of manufacture” as used herein is intended to encompass a computer program accessible from any computer-readable device, carrier (e.g., non-transitory signals), or media (e.g., non-transitory media). For example, computer-readable media can include but are not limited to magnetic storage devices (e.g., hard disk, floppy disk, magnetic strips, and so on), optical disks (e.g., compact disk (CD), digital versatile disk (DVD), and so on), smart cards, and flash memory devices (e.g., card, stick, and so on). Additionally it should be appreciated that a carrier wave can be employed to carry computer-readable electronic data such as those used in transmitting and receiving electronic mail or in accessing a network such as the Internet or a local area network (LAN). Those skilled in the art will recognize that many modifications may be made to these configurations without departing from the scope or spirit of the claimed subject matter.

Certain operations of methods according to the disclosure, or of systems executing those methods, may be represented schematically in the FIGS. or otherwise discussed herein. Unless otherwise specified or limited, representation in the FIGS. of particular operations in particular spatial order may not necessarily require those operations to be executed in a particular sequence corresponding to the particular spatial order. Correspondingly, certain operations represented in the FIGS., or otherwise disclosed herein, can be executed in different orders than are expressly illustrated or described, as appropriate for particular aspects of the disclosure. Further, in some aspects, certain operations can be executed in parallel, including by dedicated parallel processing devices, or separate computing devices configured to interoperate as part of a large system.

As used herein in the context of computer implementation, unless otherwise specified or limited, the terms “component,” “system,” “module,” “block,” and the like are intended to encompass part or all of computer-related systems that include hardware, software, a combination of hardware and software, or software in execution. For example, a component may be, but is not limited to being, a processor device, a process being executed (or executable) by a processor device, an object, an executable, a thread of execution, a computer program, or a computer. By way of illustration, both an application running on a computer and the computer can be a component. One or more components (or system, module, and so on) may reside within a process or thread of execution, may be localized on one computer, may be distributed between two or more computers or other processor devices, or may be included within another component (or system, module, and so on).

Also as used herein, unless otherwise limited or defined, “or” indicates a non-exclusive list of components or operations that can be present in any variety of combinations, rather than an exclusive list of components that can be present only as alternatives to each other. For example, a list of “A, B, or C” indicates options of: A; B; C; A and B; A and C; B and C; and A, B, and C. Correspondingly, the term “or” as used herein is intended to indicate exclusive alternatives only when preceded by terms of exclusivity, such as “either,” “one of,” “only one of,” or “exactly one of” For example, a list of “one of A, B, or C” indicates options of: A, but not B and C; B, but not A and C; and C, but not A and B. A list preceded by “one or more” (and variations thereon) and including “or” to separate listed elements indicates options of one or more of any or all of the listed elements. For example, the phrases “one or more of A, B, or C” and “at least one of A, B, or C” indicate options of: one or more A; one or more B; one or more C; one or more A and one or more B; one or more B and one or more C; one or more A and one or more C; and one or more of A, one or more of B, and one or more of C. Similarly, a list preceded by “a plurality of” (and variations thereon) and including “or” to separate listed elements indicates options of multiple instances of any or all of the listed elements. For example, the phrases “a plurality of A, B, or C” and “two or more of A, B, or C” indicate options of: A and B; B and C; A and C; and A, B, and C.

Also as used herein, unless otherwise limited or defined, the terms “about,” “substantially,” and “approximately” refer to a range of values ±5% of the numeric value that the term precedes. As a default the terms “about” and “approximately” are inclusive to the endpoints of the relevant range, but disclosure of ranges exclusive to the endpoints is also intended.

Also as used herein, unless otherwise limited or defined, “integral” and derivatives thereof (e.g., “integrally”) describe elements that are manufacture as a single piece without fasteners, adhesive, or the like to secure separate components together. For example, an element stamped as a single-piece component from a single piece of sheet metal, without rivets, screws, or adhesive to hold separately formed pieces together is an integral (and integrally formed) element. In contrast, an element formed from multiple pieces that are separately formed initially then later connected together, is not an integral (or integrally formed) element.

1. A method of controlling a first pump in a coolant distribution unit for cooling electronic components, the method comprising:
setting a control priority to a first value indicative of a client mode in which a first local controller generates a first speed signal for the first pump in response to an instruction received from a master controller;
determining a first interval since a last communication from the master controller; and
if the first interval exceeds a preset dead time, setting the control priority of the first local controller to a second value indicative of an autonomous mode in which the first local controller generates the first speed signal for the first pump based on one or more parameters stored in a memory of the first local controller.

2. The method of claim 1, further comprising generating, at the first local controller, a second speed signal based on a target speed.

3. The method of claim 2, further comprising determining that the first pump is a passive pump, and, when the first interval exceeds the preset dead time, generating, at the first local controller, a third speed signal to reduce a speed of the first pump.

4. The method of claim 1, further comprising providing a first pump cassette, including the first local controller, the first pump, a first pump drive, and at least one peripheral electronic device.

5. The method of claim 4, wherein the at least one peripheral electronic device includes a fan.

6. The method of claim 4, wherein the first pump cassette includes a first power button.

7. The method of claim 6, further comprising:
providing a second pump cassette including a second local controller, a second pump, and a second pump drive;
receiving a power button signal indicating a depression of the first power button;
generating, at the master controller, responsive to the power button signal, a first ramp instruction to increase a first speed of the first pump;
sending the first ramp instruction to the first local controller;
generating, at the master controller, responsive to the power button signal, a second ramp instruction to decrease a second speed of the second pump; and
sending the second ramp instruction to the second local controller.

8. The method of claim 7, further comprising removing the second pump cassette while the first pump of the first pump cassette continues to operate in the autonomous mode.

9. The method of claim 7, wherein communication between the master controller and the first local controller and the second local controller adheres to a Modbus protocol.

10. The method of claim 1, further comprising controlling the first pump in a reservoir pump unit of a liquid to air coolant distribution unit.

11. The method of claim 1, further comprising setting the control priority of the first local controller to the second value indicative of the autonomous mode when an emergency loss of at least one of communication or power occurs.

12. A reservoir pump unit for use in a coolant distribution unit for cooling electrical components, the reservoir pump unit including
a controller slot receiving a master controller, the master controller being configured for toolless removal from the controller slot;
a first cassette bay receiving a first pump cassette,
the first pump cassette including a first pump and a first local controller,
the first local controller including a first memory with a first control priority set at a first value indicative of a client mode in which the first local controller receives a first speed instruction from the master controller;
the first local controller determining a first interval since a last communication from the master controller; and
when the first interval exceeds a preset dead time, the first local controller setting the first control priority to a second value indicative of an autonomous mode in which the first local controller generates a first speed signal for the first pump based on one or more parameters stored in the first memory.

13. The coolant distribution unit of claim 12, further comprising:
a second cassette bay receiving a second pump cassette,
the second pump cassette including a second pump and a second local controller,
wherein the first pump cassette includes a power button; and
when the power button is depressed, the master controller generates a first ramp instruction to increase a speed of the first pump and a second ramp instruction to decrease a second speed of the second pump.

14. The reservoir pump unit of claim 13, wherein a communication between the master controller and the first local controller and the second local controller adheres to a Modbus protocol.

15. The reservoir pump unit of claim 12, wherein, when the first local controller is in the client mode, the first local controller receives an instruction from the master controller to implement a first of a plurality of operating modes.

16. The reservoir pump unit of claim 12, wherein the first pump cassette includes a locking system to engage a locking mechanism of the reservoir pump unit to selectively lock or unlock the first pump cassette relative to the reservoir pump unit.

17. The reservoir pump unit of claim 16, wherein the locking system is in electrical communication with the first local controller.

18. The reservoir pump unit of claim 12, wherein the coolant distribution unit includes at least one fan.

19. The reservoir pump unit of claim 12, wherein the reservoir pump unit is installed in a liquid to air coolant distribution unit including a plurality of fans.

20. The reservoir pump unit of claim 12, further comprising the first local controller sets the first control priority to the second value indicative of the autonomous mode when an emergency loss of at least one of communication or power occurs.
